(19) United States
(12) Patent Application Publication
(10) Pub. No.: US 2013/0337385 A1
(43) Pub. Date: Dec. 19, 2013

(54) NEGATIVE PATTERN-FORMING METHOD AND PHOTORESIST COMPOSITION

(71) Applicant: JSR CORPORATION, Tokyo (JP)

(72) Inventors: Taiichi FURUKAWA, Tokyo (JP); Koji ITO, Tokyo (JP); Hiromu MIYATA, Tokyo (JP); Hirokazu SAKAKIBARA, Tokyo (JP)

(73) Assignee: JSR CORPORATION, Tokyo (JP)

(21) Appl. No.: 13/972,963

(22) Filed: Aug. 22, 2013

Related U.S. Application Data
(63) Continuation of application No. PCT/JP2012/053570, filed on Feb. 15, 2012.

(30) Foreign Application Priority Data
Feb. 23, 2011 (JP) 2011-037640

(51) Int. Cl. G03F 7/004

(52) U.S. Cl. CPC G03F 7/004
USPC 430/285.1; 430/325

(57) ABSTRACT

A negative pattern-forming method includes providing a resist film on a substrate using a photoresist composition. The photoresist composition includes a first polymer and an organic solvent. The first polymer includes a first structural unit having an acid-generating capability. The resist film is exposed. The exposed resist film is developed using a developer that includes an organic solvent.

### CROSS-REFERENCE TO RELATED APPLICATIONS

The present application is a continuation application of International Application No. PCT/JP2012/053570, filed Feb. 15, 2012, which claims priority to Japanese Patent Application No. 2011-037640, filed Feb. 23, 2011. The contents of these applications are incorporated herein by reference in their entirety.

### BACKGROUND OF THE INVENTION

1. Field of the Invention

The present invention relates to a negative pattern-forming method and a photoresist composition.

2. Discussion of the Background

A reduction in line width of a resist pattern used for a lithographic process has been desired along with miniaturization of various electronic device (e.g., semiconductor device and liquid crystal device) structures. An ArF excimer laser has typically been used as a short-wavelength light source. A fine resist pattern having a line width of about 90 nm can be formed using ArF excimer laser light. Various resist compositions adapted to such short-wavelength radiation have been studied. For example, a photoresist composition has been known that is designed so that an acid is generated upon exposure, and a difference in solubility rate in a developer occurs between the exposed area and the unexposed area due to the catalytic effect of the acid to form a resist pattern on a substrate.

As a technique that improves the resolution of the photoresist composition using an existing system without increasing the number of steps, a pattern-forming method that utilizes an organic solvent having a polarity lower than that of an alkaline aqueous solution as the developer, has been known (see Japanese Patent Application Publication (KOKAI) No. 2000-199953, Japanese Patent Application Publication (KOKAI) No. 2008-309878, Japanese Patent Application Publication (KOKAI) No. 2008-309879). The above pattern-forming method can increase the optical contrast as compared with alkali development, and form a finer pattern.

### SUMMARY OF THE INVENTION

According to one aspect of the present invention, a negative pattern-forming method includes providing a resist film on a substrate using a photoresist composition. The photoresist composition includes a first polymer and an organic solvent. The first polymer includes a first structural unit having an acid-generating capability. The resist film is exposed. The exposed resist film is developed using a developer that includes an organic solvent.

According to another aspect of the present invention, a photoresist composition includes a first polymer and an organic solvent. The first polymer includes a first structural unit having an acid-generating capability. The photoresist composition is developed using an organic solvent, and is used to form a negative pattern.

### DESCRIPTION OF THE EMBODIMENTS

The ordinal numbers in the terms “first polymer”, “second polymer”, “third polymer”, “first structural unit”, “second structural unit”, or the like recited in the claims and SUMMARY OF THE INVENTION and ABSTRACT of the specification of the present application are merely identifiers, but does not have any other meanings, for example, a particular order and the like. Moreover, for example, the term “first polymer” itself does not imply an existence of the “second polymer”.

According to one embodiment of the invention, a negative pattern-forming method includes:

(1) forming a resist film on a substrate using a photoresist composition that includes [A] a polymer that includes a structural unit (I) having an acid-generating capability (hereinafter may be referred to as “polymer [A]”), and [F] an organic solvent;
(2) exposing the resist film; and
(3) developing the exposed resist film using a developer that includes an organic solvent.

The negative pattern-forming method according the embodiment of the invention utilizes the polymer [A] that includes the structural unit (I) having an acid-generating capability. The term “acid-generating capability” used herein refers to the capability to generate an acid upon exposure. For example, a cation dissociates from the structural unit (I) upon exposure, while an anion moiety that remains in the structural unit (I) functions as acid, or an anion dissociates from the structural unit (I) upon exposure, and functions as acid. When the polymer [A] includes the structural unit (I) having an acid-generating capability, the acid generated upon exposure is uniformly distributed over the polymer chain, and diffusion of the acid from the exposed area to the unexposed area is easily controlled. Therefore, when the photoresist composition includes the polymer [A], an acid uniformly and sufficiently functions in the exposed area, so that the solubility of the exposed area in the developer that includes an organic solvent further decreases, and roughness on the surface of the resist can be reduced. It is also possible to achieve high sensitivity as compared with a known chemically-amplified resist. The negative pattern-forming method that utilizes the above photoresist composition can suppress occurrence of roughness, and form an excellent fine pattern.

It is preferable that the structural unit (I) have a structure derived from an onium salt, diazomethane, or N-sulfonyloxyimide. The structure derived from an onium salt, diazomethane, or N-sulfonyloxyimide included in the structural unit (I) can generate an acid having sufficient strength upon exposure. Therefore, the photoresist composition exhibits improved effects, and the negative pattern-forming method that utilizes the photoresist composition can further suppress occurrence of roughness, and form an excellent fine pattern.

It is preferable that the structural unit (I) be represented by the following formula (1) or the following formula (2).

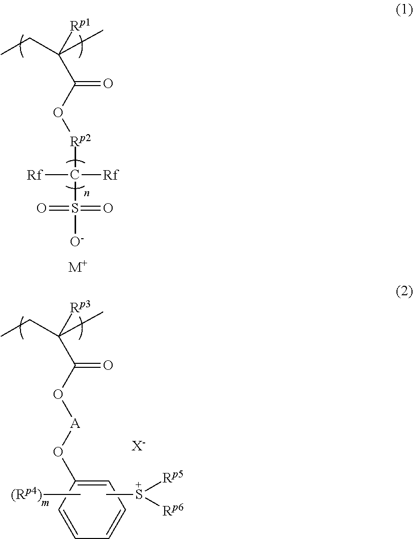

wherein R^{p1} is a hydrogen atom, a fluorine atom, a trifluoromethyl group, or an alkyl group having 1 to 3 carbon atoms, R^{p2} is a divalent organic group, Rf are independently a hydrogen atom, a fluorine atom, or a fluoroalkyl group having 1 to 3 carbon atoms, n is an integer from 0 to 6, M⁺ is an onium cation, R^{p3} is a hydrogen atom, a fluorine atom, a trifluoromethyl group, or an alkyl group having 1 to 3 carbon atoms, R^{p4}, R^{p5}, and R^{p6} are independently an organic group having 1 to 10 carbon atoms, m is an integer from 0 to 3, provided that a plurality of R^{p4} are either identical or different when m is 2 or 3, A is a methylene group, an alkylene group having 2 to 10 carbon atoms, or an arylene group having 6 to 10 carbon atoms, and X⁻ is a sulfonate anion, a carboxylate anion, or an amide anion.

When the polymer [A] included in the photoresist composition used for the negative pattern-forming method includes the structural unit represented by the formula (1) or (2) as the structural unit (I), and has the above specific structure that can generate an acid, the acid generated upon exposure is uniformly distributed over the polymer chain, and diffusion of the acid from the exposed area to the unexposed area is easily controlled. Moreover, since the exposed area exhibits high hydrophilicity, and the solubility of the exposed area in the developer that includes an organic solvent further decreases, occurrence of roughness on the surface of the resist can be suppressed. Therefore, the negative pattern-forming method that utilizes the photoresist composition can form an excellent fine pattern in which the contrast between the exposed area and the unexposed area is improved.

It is preferable that M⁺ in the formula (1) be represented by the following formula (3).

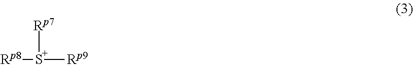

wherein R^{p7} to R^{p9} are independently a hydrocarbon group having 1 to 30 carbon atoms, provided that R^{p7} and R^{p8} may bond to each other to form a cyclic structure together with the sulfur atom to which R^{p7} and R^{p8} are bonded, and some or all of the hydrogen atoms of the hydrocarbon group are substituted with a substituent, or unsubstituted.

When the structural unit (I) represented by the formula (1) includes the cation represented by the formula (3), the negative pattern-forming method can suppress occurrence of roughness, and form an excellent fine pattern.

It is preferable that X⁻ in the formula (2) be represented by the following formula (4).

R^{p10}—SO₃⁻ (4)

wherein R^{p10} is a monovalent organic group that includes a fluorine atom.

When the structural unit (I) represented by the formula (2) includes the anion represented by the formula (4), the negative pattern-forming method can further suppress occurrence of roughness, and form a more excellent fine pattern.

It is preferable that the polymer [A] further include a structural unit (II) represented by the following formula (5).

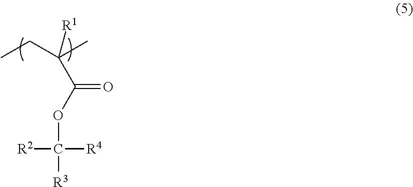

wherein R¹ is a hydrogen atom, a fluorine atom, a trifluoromethyl group, or an alkyl group having 1 to 3 carbon atoms, and R² to R⁴ are independently an alkyl group having 1 to 4 carbon atoms or an alicyclic hydrocarbon group having 4 to 20 carbon atoms, provided that R³ and R⁴ may bond to each other to form a divalent alicyclic hydrocarbon group having 4 to 20 carbon atoms together with the carbon atom to which R³ and R⁴ are bonded.

The structural unit (II) represented by the formula (5) includes an acid-labile group that easily dissociates due to an acid. When the polymer [A] includes the structural unit (II) that includes an acid-labile group in addition to the structural unit (I) having an acid-generating capability, the acid generated upon exposure efficiently causes dissociation of the acid-labile group. Therefore, the sensitivity of the photoresist composition is improved, and the negative pattern-forming method can form an excellent fine pattern.

It is preferable that the photoresist composition further include [B] a polymer that does not include the structural unit (I), but includes the structural unit (II) (hereinafter may be referred to as “polymer [B]”).

When the photoresist composition includes the polymer [B] that includes an acid-labile group in addition to the polymer [A] that includes the structural unit (I) having an acid-generating capability, the acid generated upon exposure efficiently causes dissociation of the acid-labile group included in the polymer [B]. Therefore, the negative pattern-forming method that utilizes the photoresist composition can form an excellent fine pattern in which the contrast between the exposed area and the unexposed area is improved.

The photoresist composition may further include [C] an acid generator. When the photoresist composition includes the acid generator [C] in addition to the polymer [A] that includes the structural unit (I) having an acid-generating capability, the negative pattern-forming method can form an excellent fine pattern while further suppressing occurrence of roughness.

According to another embodiment of the invention, a photoresist composition that is developed using an organic solvent, and is used to form a negative pattern, includes:

[A] a polymer that includes a structural unit (I) having an acid-generating capability; and

[F] an organic solvent.

The photoresist composition includes the polymer [A] that includes the structural unit (I) having an acid-generating capability. Since the structural unit (I) included in the polymer [A] has an acid-generating capability, the acid generated upon exposure is uniformly distributed over the polymer chain, and diffusion of the acid from the exposed area to the unexposed area is controlled. Therefore, the solubility of the exposed area in the developer that includes an organic solvent further decreases, and roughness on the surface of the resist can be reduced since the acid uniformly and sufficiently functions in the exposed area. It is also possible to achieve high sensitivity as compared with a known chemically-amplified resist.

It is preferable that the structural unit (I) have a structure derived from an onium salt, diazomethane, or N-sulfonyloxyimide. Since the structure derived from an onium salt, diazomethane, or N-sulfonyloxyimide included in the structural unit (I) can generate an acid having sufficient strength upon exposure, the photoresist composition exhibits improved sensitivity, and can further suppress occurrence of roughness.

It is preferable that the structural unit (I) be represented by the following formula (1) or the following formula (2).

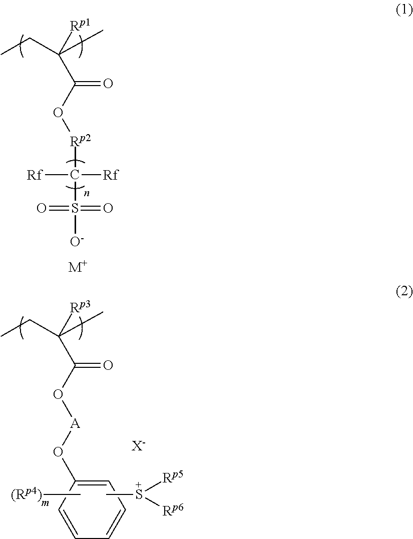

wherein R^{p1} is a hydrogen atom, a fluorine atom, a trifluoromethyl group, or an alkyl group having 1 to 3 carbon atoms, R^{p2} is a divalent organic group, Rf are independently a hydrogen atom, a fluorine atom, or a fluoroalkyl group having 1 to 3 carbon atoms, n is an integer from 0 to 6, M⁺ is an onium cation, R^{p3} is a hydrogen atom, a fluorine atom, a trifluoromethyl group, or an alkyl group having 1 to 3 carbon atoms, R^{p4}, R^{p5}, and R^{p6} are independently an organic group having 1 to 10 carbon atoms, m is an integer from 0 to 3, provided that a plurality of R^{p4} are either identical or different when m is 2 or 3, A is a methylene group, an alkylene group having 2 to 10 carbon atoms, or an arylene group having 6 to 10 carbon atoms, and X⁻ is a sulfonate anion, a carboxylate anion, or an amide anion.

Since the polymer [A] included in the photoresist composition includes the above specific structure that can generate an acid, the acid is uniformly distributed over the polymer chain, and diffusion of the acid from the exposed area to the unexposed area is controlled. Moreover, since the exposed area exhibits high hydrophilicity, and the solubility of the exposed area in the developer that includes an organic solvent further decreases, the photoresist composition can suppress occurrence of roughness on the surface of the resist.

The negative pattern-forming method according to the embodiment of the invention utilizes the photoresist composition that includes the polymer having an acid-generating capability. Since the acid generated upon exposure is uniformly distributed over a resist film formed of the photoresist composition, the resist film exhibits excellent sensitivity, ensures that the exposed area is scarcely soluble in a developer that includes an organic solvent, and can suppress occurrence of roughness. Therefore, the negative pattern-forming method according to the embodiment of the invention can suppress occurrence of roughness, and form a finer pattern with high accuracy. The embodiments will now be described in detail.

### Negative Pattern-Forming Method

A negative pattern-forming method according to one embodiment of the invention includes:

(1) forming a resist film on a substrate using a photoresist composition that includes [A] a polymer that includes a structural unit (I) having an acid-generating capability, and [F] an organic solvent (hereinafter may be referred to as “step (1)”);
(2) exposing the resist film (hereinafter may be referred to as “step (2)”); and
(3) developing the exposed resist film using a developer that includes an organic solvent (hereinafter may be referred to as “step (3)”). Each step is described in detail below. Note that the details of the photoresist composition used for the negative pattern-forming method are described later.

### Step (1)

In the step (1), the photoresist composition is applied to the substrate either directly or through an underlayer film or the like to form a resist film. A silicon wafer, an aluminum-coated wafer, or the like may be used as the substrate. An organic or inorganic antireflective film as disclosed in Japanese Patent Publication (KOKOKU) No. 6-12452, Japanese Patent Application Publication (KOKAI) No. 59-93448, or the like may be formed on the substrate. The underlayer film or the like is not particularly limited as long as the underlayer film or the like is formed of a material that is insoluble in a developer used for development after exposure, and can be etched by a known etching method. For example, a material that is normally used as an undercoat material when producing a semiconductor device or a liquid crystal display device may be used as the material for forming the underlayer film or the like.

The photoresist composition may be applied by spin coating, cast coating, roll coating, or the like. The thickness of the resist film is normally 0.01 to 1 μm, and preferably 0.01 to 0.5 μm.

The resist film formed by applying the photoresist composition may optionally be prebaked (PB) to vaporize the solvent. The PB temperature is appropriately selected depending on the composition (components) of the photoresist composition, but is normally about 30 to 200° C., and preferably 50 to 150° C.

A protective film as disclosed in Japanese Patent Application Publication (KOKAI) No. 5-188598 or the like may be formed on the resist layer in order to prevent the effects of basic impurities and the like contained in the environmental atmosphere. In order to prevent elution of the acid generator and the like from the resist layer, a liquid immersion lithography protective film as disclosed in Japanese Patent Application Publication (KOKAI) No. 2005-352384 or the like may also be formed on the resist layer. Note that these techniques may be used in combination.

### Step (2)

In the step (2), the desired area of the resist film formed by the step (1) is subjected to reduced projection exposure via a mask having a specific pattern (e.g., dot pattern or line pattern). For example, the desired area of the resist film may be subjected to reduced projection exposure via an isolated line pattern mask to form an isolated space pattern. The resist film may be exposed a plurality of times using the desired pattern mask and another pattern mask. In this case, it is preferable to continuously (successively) expose the resist film. For example, the desired area of the resist film may be subjected to first reduced projection exposure via a line-and-space pattern mask, and then subjected to second reduced projection exposure so that the exposed areas (lines) intersect. It is preferable that the area subjected to the first reduced projection exposure perpendicularly intersect the area subjected to the second reduced projection exposure. This makes it easy to form a circular contact hole pattern in the unexposed area enclosed by the exposed area. Note that liquid immersion lithography that utilizes an immersion liquid may be used for exposure. Examples of the immersion liquid include water, a fluorine-based inert liquid, and the like. It is preferable that the immersion liquid be transparent to the exposure wavelength, and have a temperature coefficient of the refractive index as small as possible so that distortion of an optical image projected onto the film is minimized. When using an ArF excimer laser light (wavelength: 193 nm) as exposure light, it is preferable to use water from the viewpoint of availability and ease of handling

Exposure light used for exposure is appropriately selected from charged particle rays (e.g., electron beams (EB)), ultraviolet rays, deep ultraviolet rays, extreme ultraviolet (EUV) light, X-rays, and the like depending on the type of acid generator. It is preferable to use deep ultraviolet rays such as ArF excimer laser light or KrF excimer laser light (wavelength: 248 nm), extreme ultraviolet (EUV) light, X-rays, or charged particle rays. It is more preferable to use ArF excimer laser light, extreme ultraviolet (EUV) light, X-rays, or electron beams. The exposure conditions (e.g., dose) may be appropriately selected depending on the composition (components) of the photoresist composition, the type of additive, and the like. The negative pattern-forming method according to one embodiment of the invention may include a plurality of exposure steps. An identical or different light source may be used for each exposure step. Note that it is preferable to use ArF excimer laser light or electron beams in the first exposure step.

It is preferable to perform post-exposure bake (PEB) after exposure. The acid-labile group included in the photoresist composition dissociates smoothly due to PEB. The PEB temperature is normally 30 to 200° C., and preferably 50 to 170° C.

### Step (3)

In the step (3), the resist film exposed by the step (2) is developed using a developer that includes an organic solvent to form a negative pattern (e.g., trench pattern and/or hole pattern). The term “negative pattern” used herein refers to a pattern obtained by selectively dissolving and removing a low-dose exposed area and an unexposed area using a developer. The organic solvent included in the developer is preferably at least one solvent selected from the group consisting of alcohol-based solvents, ether-based solvents, ketone-based solvents, amide-based solvents, ester-based solvents, and hydrocarbon-based solvents. Examples of these organic solvents include those mentioned below in connection with the solvent [F] that is included in the photoresist composition.

The organic solvent included in the developer is preferably butyl acetate, isoamyl acetate, methyl n-pentyl ketone, or anisole. These organic solvents may be used either alone or in combination.

The content of the organic solvent in the developer is normally 80 mass % or more, preferably 90 mass % or more, and still more preferably 99 mass % or more. When the content of the organic solvent in the developer is 80 mass % or more, excellent developability can be obtained, and a pattern that exhibits excellent lithographic performance can be formed. Examples of the components other than the organic solvent include water, silicone oil, a surfactant, and the like.

An appropriate amount of a surfactant may optionally be added to the developer. An ionic or nonionic fluorine-based and/or silicon-based surfactant or the like may be used as the surfactant.

Examples of the development method include a dipping method that immerses the substrate in a bath filled with the developer for a given time, a puddle method that allows the developer to be present on the surface of the substrate for a given time due to surface tension, a spray method that sprays the developer onto the surface of the substrate, a dynamic dispensing method that applies the developer to the substrate that is rotated at a constant speed while scanning with a developer application nozzle at a constant speed, and the like.

The resist film may be rinsed with a rinse agent after the step (3) (development). It is preferable that the rinse agent include an organic solvent in the same manner as the developer. Scum can be efficiently washed away by utilizing such a rinse agent. A hydrocarbon-based solvent, a ketone-based solvent, an ester-based solvent, an alcohol-based solvent, an amide-based solvent, or the like is preferable as the rinse agent. Among these, an alcohol-based solvent and an ester-based solvent are preferable, and a monohydric alcohol-based solvent having 6 to 8 carbon atoms is more preferable. Examples of the monohydric alcohol having 6 to 8 carbon atoms include linear, branched, or cyclic monohydric alcohols such as 1-hexanol, 1-heptanol, 1-octanol, 4-methyl-2-pentanol, 2-hexanol, 2-heptanol, 2-octanol, 3-hexanol, 3-heptanol, 3-octanol, 4-octanol, and benzyl alcohol. Among these, 1-hexanol, 2-hexanol, 2-heptanol, and 4-methyl-2-pentanol are preferable.

The rinse agent may include one or more types of each component. The water content in the rinse agent is preferably 10 mass % or less, more preferably 5 mass % or less, and still more preferably 3 mass % or less. When the water content in the rinse agent is 10 mass % or less, excellent developability can be obtained. Note that a surfactant (described later) may be added to the rinse agent.

Examples of the rinse method include a spin method that applies the rinse agent to the substrate that is rotated at a constant speed, a dipping method that immerses the substrate in a container filled with the rinse agent for a given time, a spray method that sprays the rinse agent onto the surface of the substrate, and the like.

### Photoresist Composition

The photoresist composition that is used for the negative pattern-forming method according to the embodiments of the invention includes the polymer [A] that includes the structural unit (I) having an acid-generating capability, and the organic solvent [F]. The photoresist composition preferably further includes the polymer [B] and/or the acid generator [C]. Note that the photoresist composition may further include an additional optional component as long as the advantageous effects of the invention are not impaired. Each component is described in detail below.

### Polymer [A]

The polymer [A] includes the structural unit (I) having an acid-generating capability. It is preferable that the polymer [A] further include the structural unit (II). The polymer [A] may further include an additional structural unit as long as the advantageous effects of the invention are not impaired. Each structural unit is described in detail below.

### Structural Unit (I)

The structural unit (I) has an acid-generating capability. When the polymer [A] includes the structural unit (I) having an acid-generating capability, the acid generated upon exposure is uniformly distributed over the polymer chain, and diffusion of the acid from the exposed area to the unexposed area is controlled. Therefore, the solubility of the exposed area in the developer that includes an organic solvent further decreases, and roughness on the surface of the resist can be reduced since the acid uniformly and sufficiently functions in the exposed area. It is also possible to achieve high sensitivity as compared with a known chemically-amplified resist.

It is preferable that the structural unit (I) have a structure derived from an onium salt, diazomethane, or N-sulfonyloxyimide. It is more preferable that the structural unit (I) have a structure derived from an onium salt.

Examples of the structure derived from an onium salt include structures represented by the following formulas (i) and (ii), and the like.

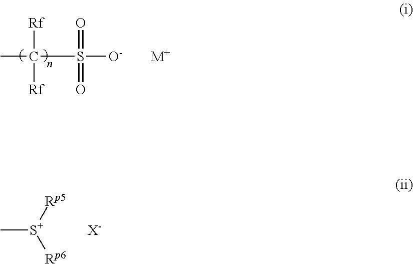

wherein Rf, n, and M⁺ are the same as defined for the formula (1), and R^{p5}, R^{p6}, and X⁻ are the same as defined for the formula (2).

The polymer [A] preferably includes the structural unit (I) represented by the formula (1) or (2) as the structural unit (I) that has a structure derived from an onium salt.

### Structural Unit (I) Represented by Formula (1)

In the formula (I), R^{p1} is a hydrogen atom, a fluorine atom, a trifluoromethyl group, or an alkyl group having 1 to 3 carbon atoms, R^{p2} is a divalent organic group, Rf are independently a hydrogen atom, a fluorine atom, or a fluoroalkyl group having 1 to 3 carbon atoms, n is an integer from 0 to 6, and M⁺ is an onium cation.

Examples of the alkyl group having 1 to 3 carbon atoms represented by R^{p1} include a methyl group, an ethyl group, and a propyl group. Among these, a methyl group is preferable. Note that R^{p1} is preferably a hydrogen atom or a methyl group.

Examples of the divalent organic group represented by R^{p2} include a hydrocarbon group having 1 to 20 carbon atoms, a group represented by —R^{p21}—R^{p22} and the like. Note that R^{p21} is a hydrocarbon group having 1 to 20 carbon atoms, and R^{p22} is —O—, —CO—, —COO—, —OCO—, —NH—, —NHCO—, —CONH—, or —NHCOO—.

Examples of the hydrocarbon group having 1 to 20 carbon atoms include chain-like hydrocarbon groups such as a methylene group, an ethanediyl group, a propanediyl group, a butanediyl group, a pentanediyl group, a hexanediyl group, and a decanediyl group; alicyclic hydrocarbon groups obtained by removing two hydrogen atoms from an alicyclic structure (compound) (e.g., cyclopentane, cyclohexane, dicyclohexane, tricyclodecane, tetracyclododecane, and adamantane); aromatic hydrocarbon groups such as a phenylene group, a naphthylene group, and a biphenylene group; and the like. Note that some or all of the hydrogen atoms of these hydrocarbon groups may be substituted with a fluorine atom or the like. Among these, chain-like hydrocarbon groups and alicyclic hydrocarbon groups are preferable, chain-like hydrocarbon groups are more preferable, a methylene group, an ethanediyl group, a propanediyl group, a butanediyl group, and a pentanediyl group are still more preferable, and a methylene group and an ethanediyl group are particularly preferable.

Examples of the hydrocarbon group having 1 to 20 carbon atoms represented by R^{p21} include those mentioned above in connection with the hydrocarbon group having 1 to 20 carbon atoms represented by R^{p2}.

Examples of the group represented by —R^{p21}—R^{p22}— include —CH₂—O—, —CH₂—CO—, —CH₂—COO—, —CH₂—OCO—, —CH₂—NH—, —CH₂—NHCO—, —CH₂—CONH—, —CH₂—NHCOO—, —CH₂—CH₂—O—, —CH₂—CH₂—CO—, —CH₂—CH₂—COO—, —CH₂—CH₂—OCO—, —CH₂—CH₂—NH—, —CH₂—CH₂—NHCO—, —CH₂—CH₂—CONH—, —CH₂—CH₂—NHCOO—, —CH₂—CH₂—CH₂—O—, —CH₂—CH₂—CH₂—CO—, —CH₂—CH₂—CH₂—COO—, —CH₂—CH₂—CH₂—OCO—, —CH₂—CH₂—CH₂—NH—, —CH₂—CH₂—CH₂—NHCO—, —CH₂—CH₂—CH₂—CONH—, —CH₂—CH₂—CH₂—NHCOO—, —CH₂—CH₂—CHF—NHCOO—, —CH₂—CH₂—CH₂—CH₂—O—, —CH₂—CH₂—CH₂—CH₂—CO—, —CH₂—CH₂—CH₂—CH₂—COO—, —CH₂—CH₂—CH₂—CH₂—OCO—, —CH₂—CH₂—CH₂—CH₂—NH—, —CH₂—CH₂—CH₂—CH₂—NHCO—, —CH₂—CH₂—CH₂—CH₂—CONH—, —CH₂—CH₂—CH₂—CH₂—NHCOO—, —CH₂—CH₂—CH₂—CHF—NHCOO—, —CH₂—CH₂—CH₂—CH₂—CH₂—CONH—, —CH₂—CH₂—CH₂—CH₂—CH₂—NHCOO—, —CH₂—CH₂—CH₂—CH₂—CHF—NHCOO—, and the like. Among these, —CH₂—NHCOO—, —CH₂—CH₂—NHCOO—, and —CH₂—CH₂—CH₂—NHCOO— are preferable, and —CH₂—CH₂—NHCOO— is more preferable. Note that it is preferable that R^{p21} in the group represented by —R^{p21}—R^{p22}— be bonded to the ester group in the formula (1).

Examples of the fluoroalkyl group having 1 to 3 carbon atoms represented by Rf include a monofluoromethyl group, a difluoromethyl group, a trifluoromethyl group, a 1-fluoroethyl group, a 1,2-difluoroethyl group, a 1,1,2,2-tetrafluoroethyl group, and the like. Rf is preferably a hydrogen atom or a fluorine atom, and more preferably a fluorine atom.

n is preferably an integer from 0 to 4, more preferably an integer from 1 to 3, and still more preferably 1 or 2.

Examples of the onium cation represented by M⁺ include a sulfonium cation, an iodonium cation, and the like. The onium cation represented by M⁺ is preferably at least one onium cation selected from the group consisting of the sulfonium cation represented by the formula (3) and the iodonium cation represented by the formula (6).

### Sulfonium Cation Represented by Formula (3)

In the formula (3), R^{p7} to R^{p9} are independently a hydrocarbon group having 1 to 30 carbon atoms, provided that R^{p7} and R^{p8} may bond to each other to form a cyclic structure together with the sulfur atom to which R^{p7} and R^{p8} are bonded, and some or all of the hydrogen atoms of the hydrocarbon group are substituted with a substituent, or unsubstituted.

Examples of the hydrocarbon group having 1 to 30 carbon atoms represented by R^{p7} to R^{p9} include monovalent chain-like hydrocarbon groups such as a methyl group, an ethyl group, an n-propyl group, an n-butyl group, and an n-pentyl group; monovalent alicyclic hydrocarbon groups such as a cyclobutyl group, a cyclopentyl group, a cyclohexyl group, a dicyclopentyl group, a tricyclodecyl group, a tetracyclododecyl group, and an adamantyl group; monovalent hydrocarbon groups that include the above alicyclic structure; monovalent aromatic hydrocarbon groups such as a phenyl group, a naphthyl group, an anthryl group, and a biphenyl group; monovalent hydrocarbon groups that include an aromatic ring; and the like. Among these, monovalent aromatic hydrocarbon groups are preferable, and a phenyl group is more preferable.

Examples of a substituent that may substitute the hydrocarbon group include a halogen atom, a hydroxyl group, a carboxyl group, a cyano group, a nitro group, a halogenated hydrocarbon group, an alkyl group, an alkoxy group, an amino group, a thiol group, an organic sulfonyl group (RSO₂—), and the like. R is an alkyl group, a cycloalkyl group, or an aryl group. Among these, a hydroxyl group, an alkyl group, an alkoxy group, and a cyclohexylsulfonyl group are preferable, and a cyclohexylsulfonyl group is more preferable.

Specific examples of the sulfonium cation represented by the formula (3) include the cations represented by the following formulas (i-1) to (i-23), and the like.

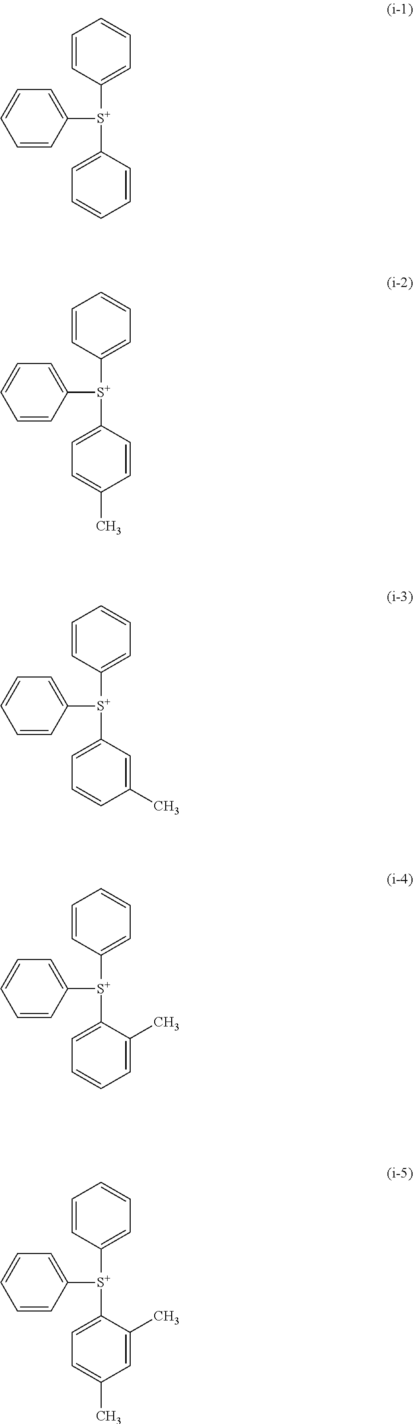 [SMILES: c1ccc([S+](c2ccccc2)c2ccccc2)cc1 ; Cc1ccc([S+](c2ccccc2)c2ccccc2)cc1 ; Cc1cccc([S+](c2ccccc2)c2ccccc2)c1 ; Cc1ccccc1[S+](c1ccccc1)c1ccccc1 ; Cc1ccc([S+](c2ccccc2)c2ccccc2)c(C)c1]

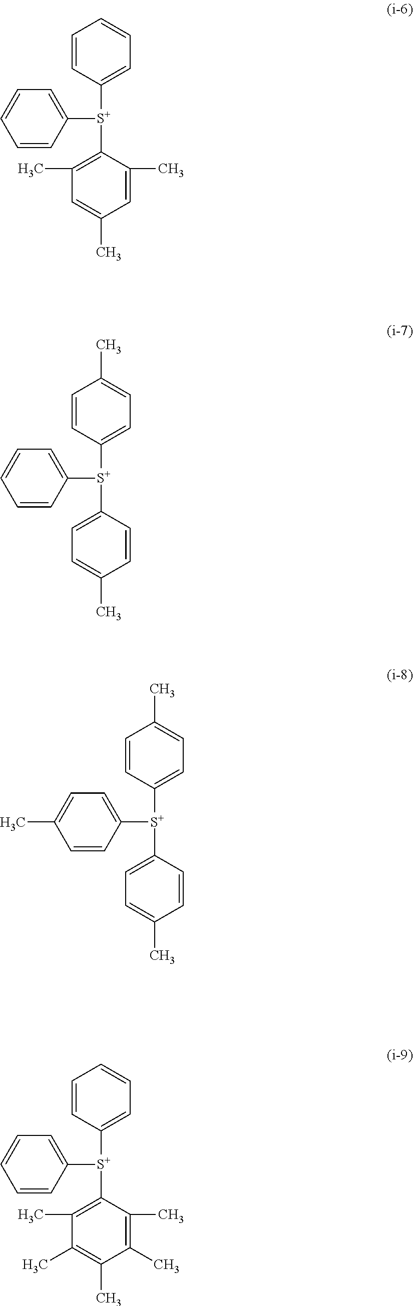

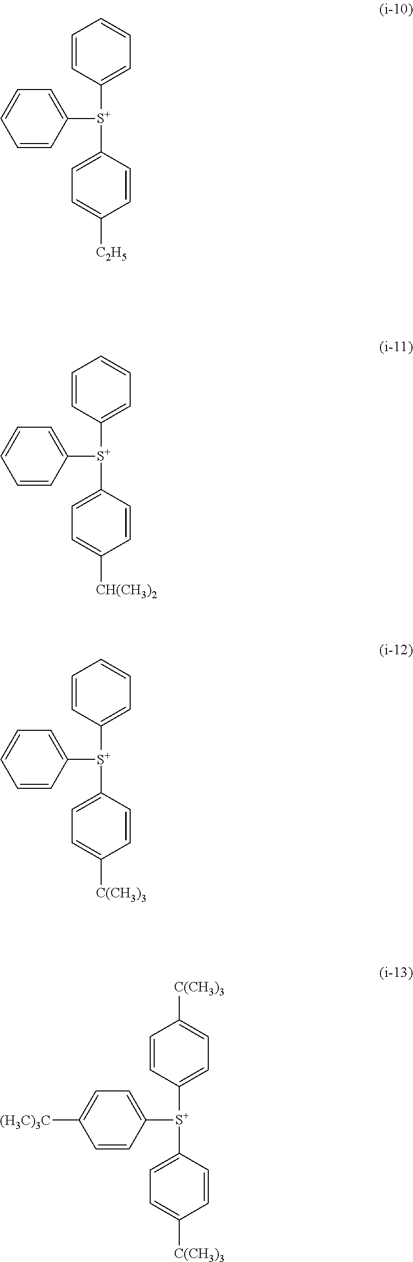 [SMILES: CCc1ccc([S+](c2ccccc2)c2ccccc2)cc1 ; CC(C)c1ccc([S+](c2ccccc2)c2ccccc2)cc1 ; CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1]

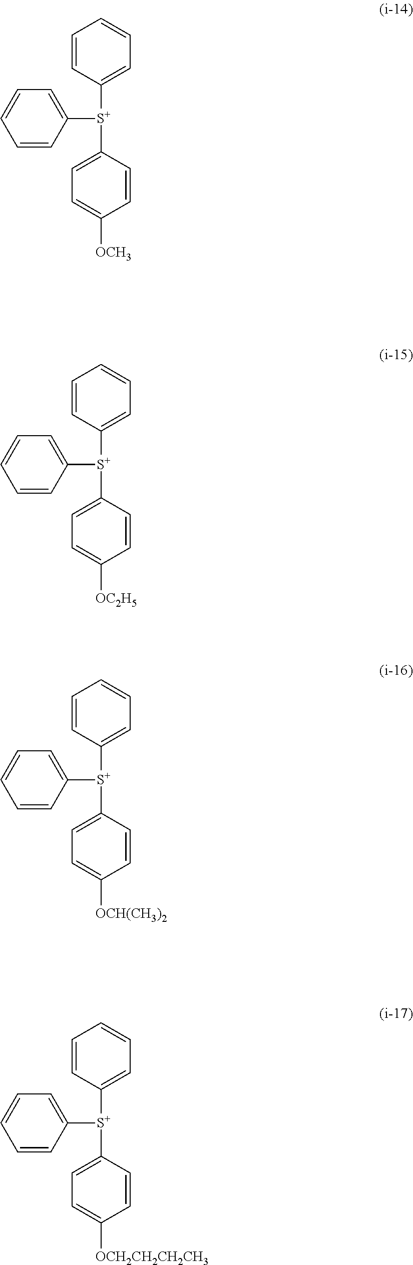

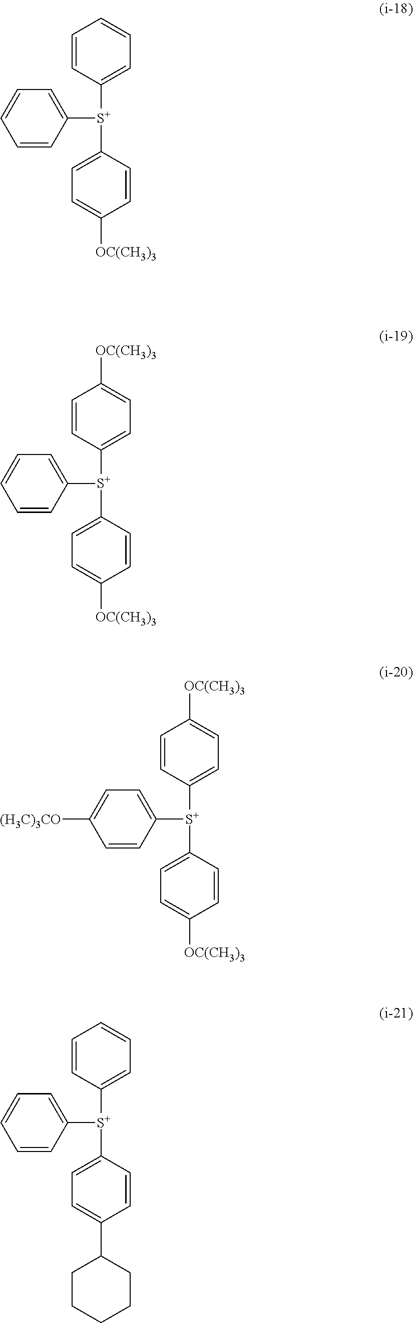

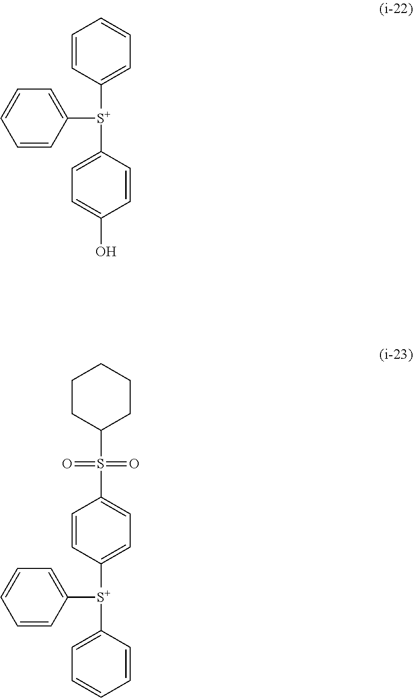 [SMILES: Oc1ccc([S+](c2ccccc2)c2ccccc2)cc1 ; O=S(=O)(c1ccc([S+](c2ccccc2)c2ccccc2)cc1)C1CCCCC1]

Among these, the sulfonium cations represented by the formulas (i-1) and (i-23) are preferable.

### Iodonium Cation Represented by Formula (6)

R^{p11}—I⁺R^{p11} (6)

In the formula (6), R^{p11} are independently a hydrocarbon group having 1 to 30 carbon atoms or a heterocyclic organic group having 4 to 30 ring atoms (nucleus atoms), provided that R^{p11} may bond to each other to form a cyclic structure together with the iodine atom, and some or all of the hydrogen atoms of the hydrocarbon group and the heterocyclic organic group may be substituted with a substituent.

Examples of the hydrocarbon group having 1 to 30 carbon atoms represented by R^{p11} include those mentioned above in connection with the hydrocarbon group having 1 to 30 carbon atoms represented by R^{p7} to R^{p9} in the formula (3). Among these, monovalent aromatic hydrocarbon groups are preferable, and a phenyl group is more preferable.

Examples of a substituent that may substitute the hydrocarbon group and the heterocyclic organic group include those mentioned above in connection with a substituent that may substitute the hydrocarbon group represented by R^{p7} to R^{p9} in the formula (3). Among these, a halogen atom, a nitro group, a halogenated hydrocarbon group, an alkyl group, and an alkoxy group are preferable.

The monovalent onium cation represented by M⁺ is preferably the sulfonium cation represented by the formula (3), and more preferably the sulfonium cation represented by the formula (i-1) or (i-23).

The monovalent onium cation represented by M⁺ in the formula (1) may be produced by the method described in Advances in Polymer Science, vol. 62, pp. 1-48 (1984), for example.

Examples of the structural unit (I) represented by the formula (1) include structural units represented by the following formulas (1-1) to (1-8), and the like.

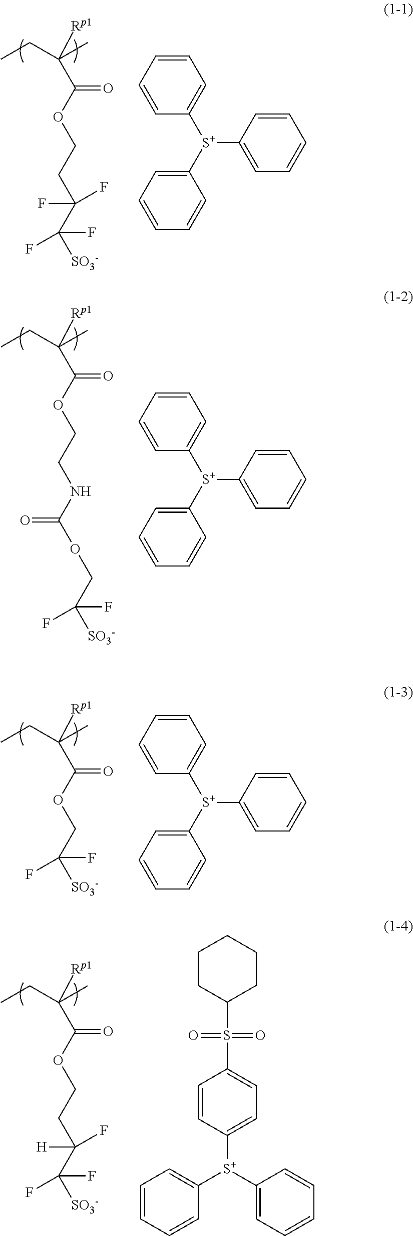

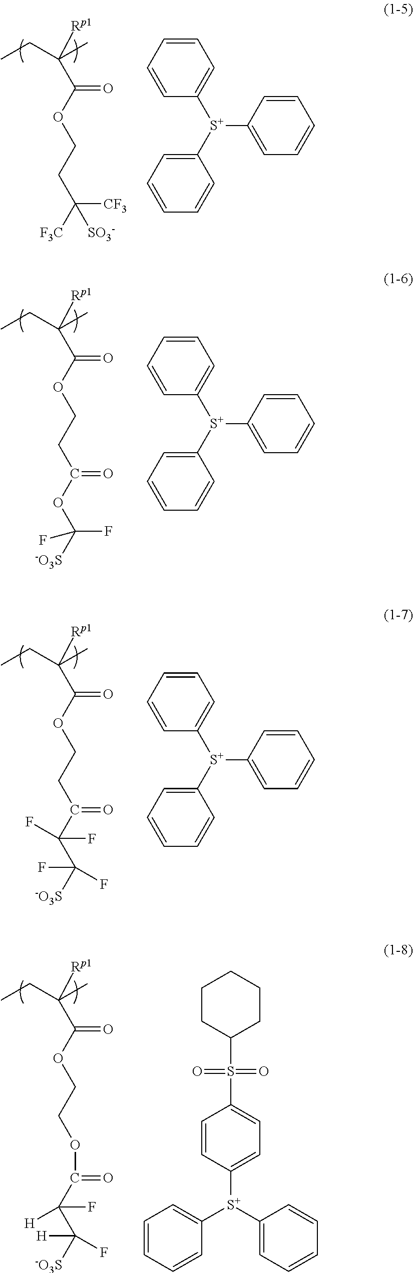

wherein R^{p1} is the same as defined for the formula (1).

Among these, the structural units represented by the formulas (1-1) to (1-4) are preferable.

The structural unit represented by the formula (1) is configured so that the cation represented by M⁺ dissociates from the polymer chain upon exposure, while the anion moiety remains in the polymer chain, and functions as an acid.

Examples of a monomer that produces the structural unit represented by the formula (1) include a compound represented by the following formula (1′), and the like.

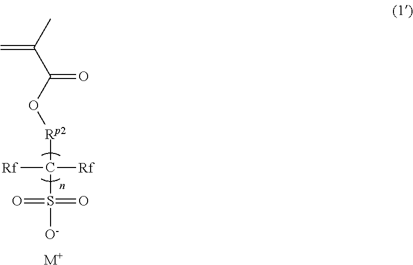

wherein R^{p2}, Rf, n, and M⁺ are the same as defined for the formula (1).

The compound represented by the formula (1′) may be synthesized by a known method.

Examples of the compound represented by the formula (1′) include the compounds represented by the following formulas (1′-1) to (1′-8), and the like.

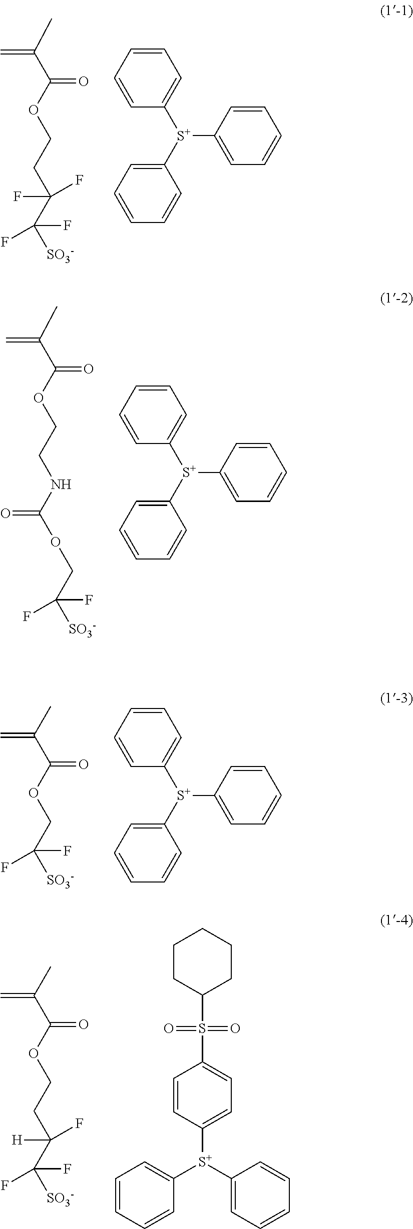

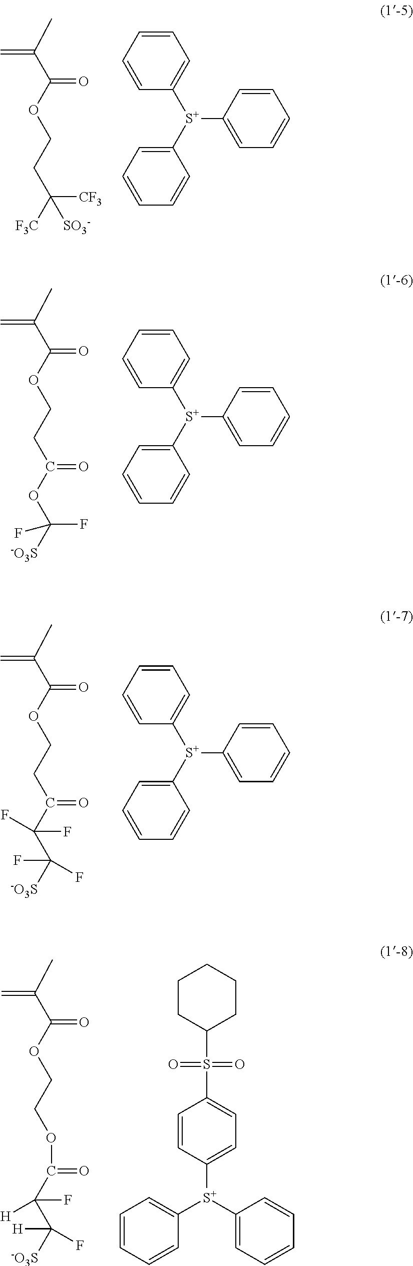

### Structural Unit (I) Represented by Formula (2)

In the formula (2), R^{p3} is a hydrogen atom, a fluorine atom, a trifluoromethyl group, or an alkyl group having 1 to 3 carbon atoms, R^{p4}, R^{p5}, and R^{p6} are independently an organic group having 1 to 10 carbon atoms, m is an integer from 0 to 3, provided that a plurality of R^{p4} are either identical or different when m is 2 or 3, A is a methylene group, an alkylene group having 2 to 10 carbon atoms, or an arylene group having 6 to 10 carbon atoms, and X⁻ is a sulfonate anion, a carboxylate anion, or an amide anion.

Examples of the alkyl group having 1 to 3 carbon atoms represented by R^{p3} include a methyl group, an ethyl group, and a propyl group. Among these, a methyl group is preferable. R^{p3} is preferably a hydrogen atom or a methyl group.

Examples of the alkylene group having 2 to 10 carbon atoms represented by A include an ethylene group, a 1,3-propylene group, a 1,2-propylene group, a tetramethylene group, a pentamethylene group, a hexamethylene group, a heptamethylene group, an octamethylene group, a nonamethylene group, a decamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, and the like.

Examples of the arylene group having 6 to 10 carbon atoms represented by A include a phenylene group, a naphthylene group, an anthrylene group, a phenanthrylene group, and the like. Among these, alkylene groups such as an ethylene group and a propylene group are preferable since the resulting compound exhibits excellent stability.

Examples of the monovalent organic group having 1 to 10 carbon atoms represented by R^{p4}, R^{p5}, and R^{p6} include an alkyl group having 1 to 10 carbon atoms, an alkoxy group, an aryl group, and the like.

Examples of the alkyl group include a methyl group, an ethyl group, an n-propyl group, an i-propyl group, an n-butyl group, a 2-methylpropyl group, a 1-methylpropyl group, a t-butyl group, a pentyl group, a hexyl group, a hydroxymethyl group, a hydroxyethyl group, a trifluoromethyl group, and the like.

Examples of the alkoxy group include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like.

Examples of the aryl group include a phenyl group, a naphthyl group, and the like.

R^{p4} is preferably an alkoxy group, and more preferably a methoxy group. R^{p5} and R^{p6} are preferably an aryl group, more preferably a phenyl group or a naphthyl group, and still more preferably a phenyl group.

m is preferably 0 or 1, and more preferably 0.

X⁻ is preferably a sulfonate anion or a carboxylate anion, more preferably a sulfonate anion, and still more preferably the sulfonate anion represented by the formula (4).

In the formula (4), R^{p10} is a monovalent organic group that includes a fluorine atom.

Examples of the monovalent organic group include chain-like alkyl groups having 1 to 10 carbon atoms, alicyclic hydrocarbon groups (hydrocarbon groups having an alicyclic skeleton) having 6 to 20 carbon atoms, and the like. The chain-like alkyl group or the alicyclic hydrocarbon group may include —O—, —S—, —C(O)O—, or —C(O)N— between carbon atoms.

Examples of the chain-like alkyl group having 1 to 10 carbon atoms (that includes a fluorine atom) represented by R^{p10} include a trifluoromethyl group, a trifluoroethyl group, a pentafluoropropyl group, a hexafluoroisopropyl group, a hexafluoro(2-methyl)isopropyl group, a heptafluorobutyl group, a heptafluoroisopropyl group, an octafluoroisobutyl group, a nonafluorohexyl group, a nonafluorobutyl group, a perfluoroisopentyl group, a perfluorooctyl group, a perfluoro(trimethyl)hexyl group, and the like. Among these, a nonafluorobutyl group is preferable.

Examples of the alicyclic hydrocarbon group having 6 to 20 carbon atoms (that includes a fluorine atom) represented by R^{p10} include the groups represented by the following formulas.

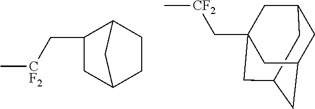

Examples of the chain-like alkyl group or the alicyclic hydrocarbon group (that includes a fluorine atom) represented by R^{p10} that includes —O—, —S—, —C(O)O—, or —C(O)N— between carbon atoms include the group represented by the following formula.

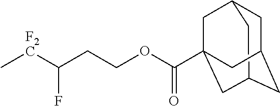 [SMILES: CC(F)(F)C(F)CCOC(=O)C12CC3CC(CC(C3)C1)C2]

Some or all of the hydrogen atoms of the sulfonate anion may be substituted with a substituent. Examples of the substituent include an alkyl group, an aryl group, an aralkyl group, a cycloalkyl group, an alkyl halide group, an aryl halide group, an aralkyl halide group, a cycloalkyl oxide group, a cycloalkyl halide group, and the like. Note that the halogen atom included in the alkyl halide group, the aryl halide group, the aralkyl halide group, and the cycloalkyl halide group is preferably a fluorine atom.

Examples of the sulfonate anion represented by the formula (4) include the sulfonate anions represented by the following formulas (4-1) to (4-17), and the like.

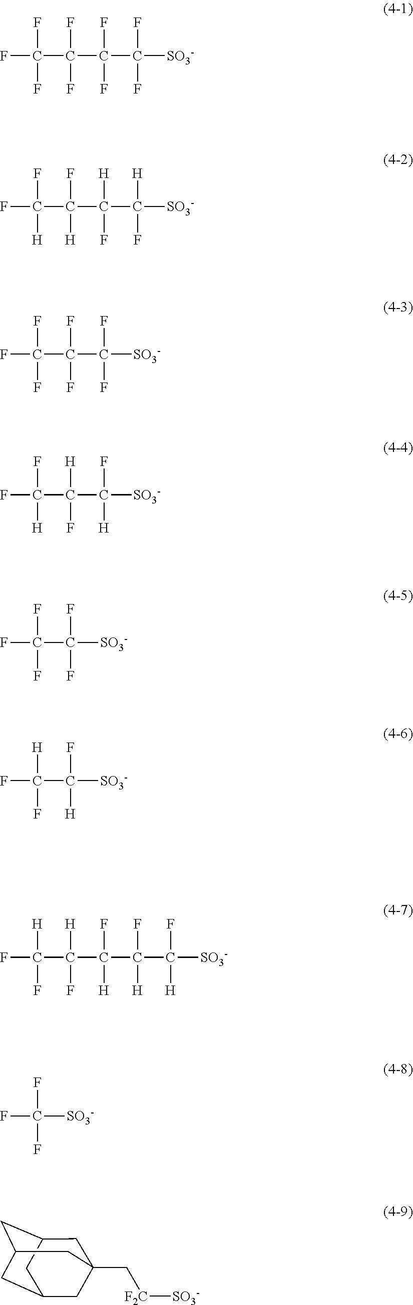

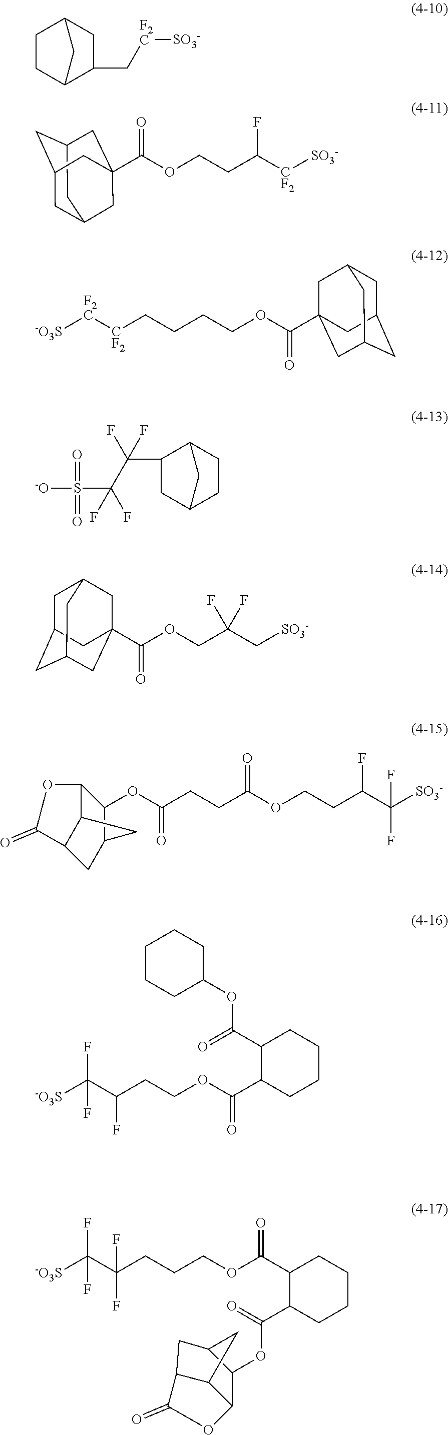

Among these, the sulfonate anions represented by the formulas (4-1), (4-9), (4-10), and (4-11) are preferable.

Examples of the structural unit (I) represented by the formula (2) include structural units represented by the following formulas (2-1) to (2-18), and the like.

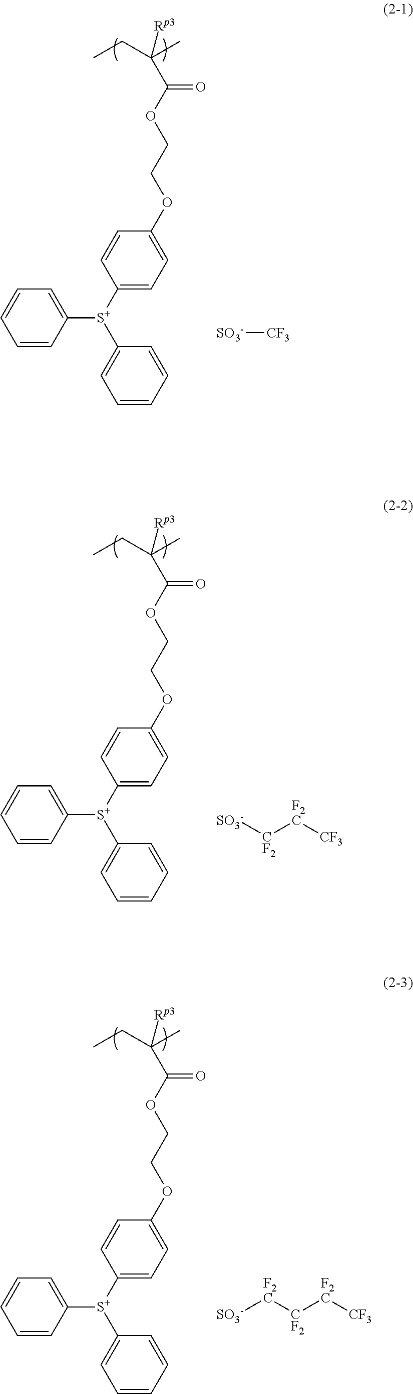

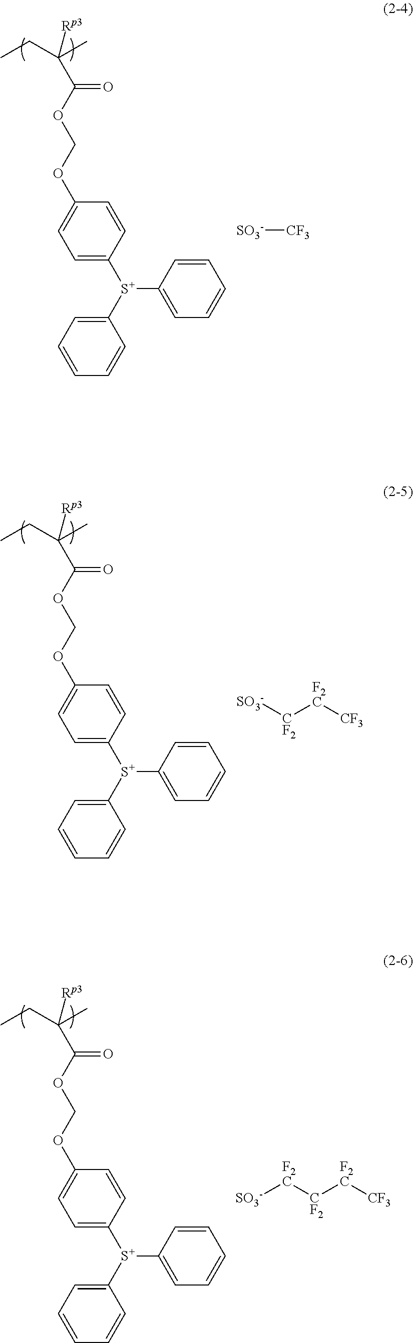

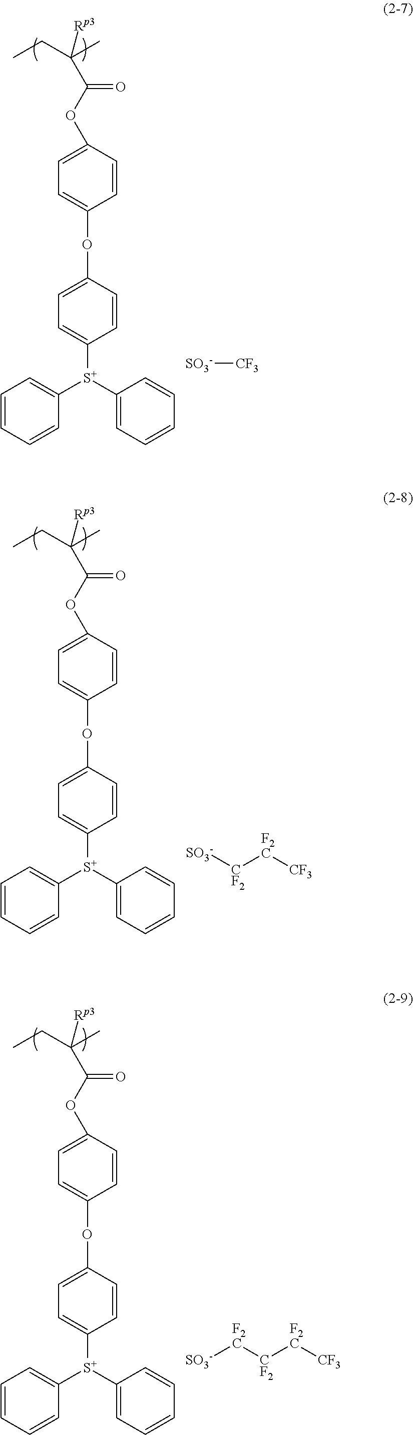

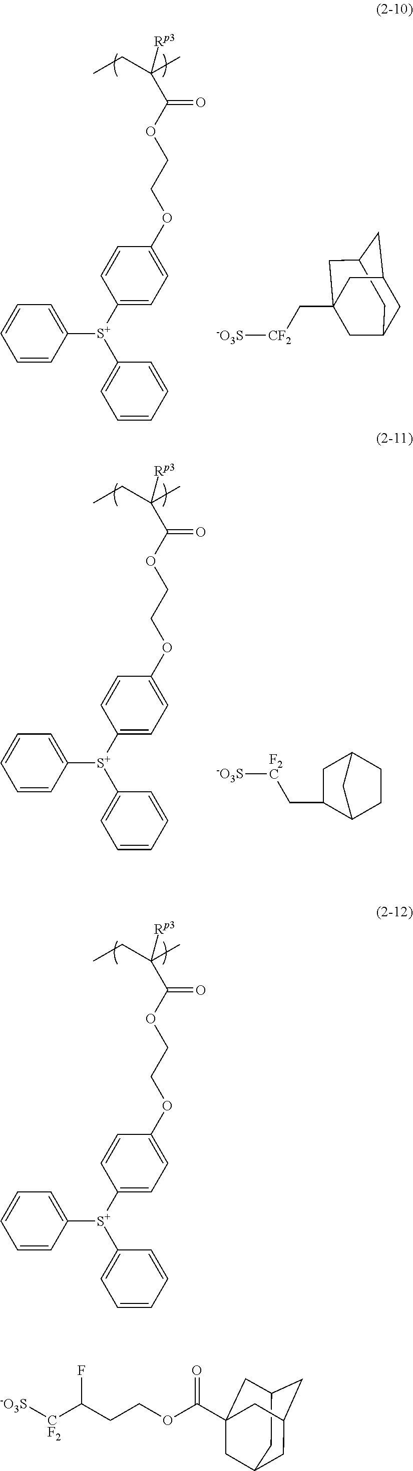

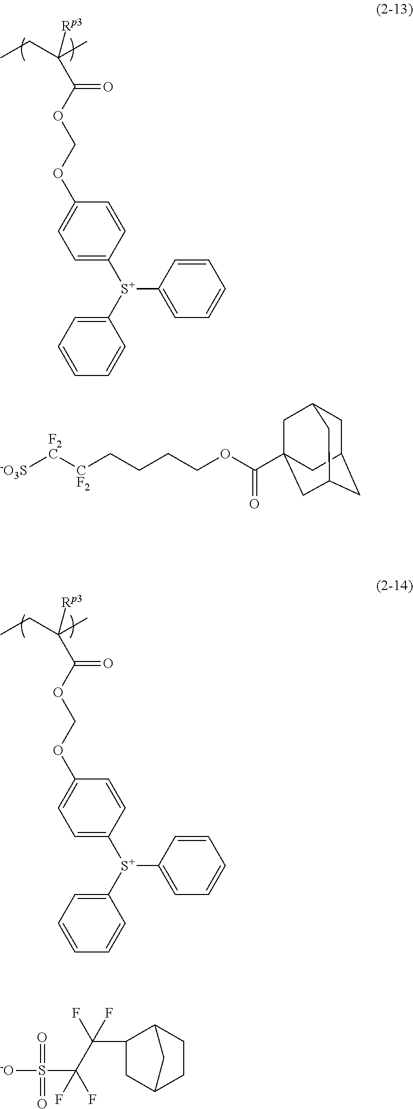

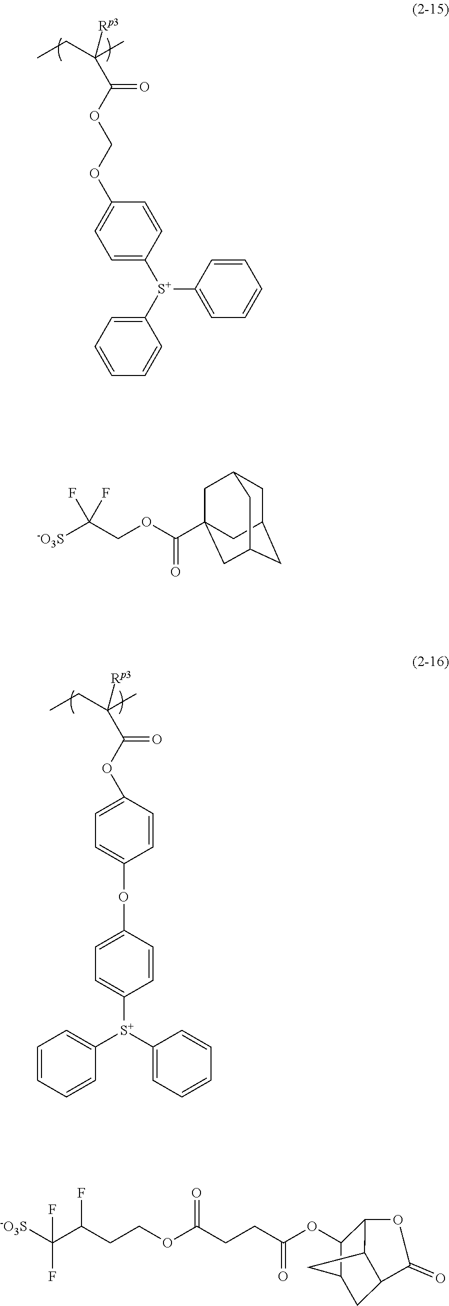

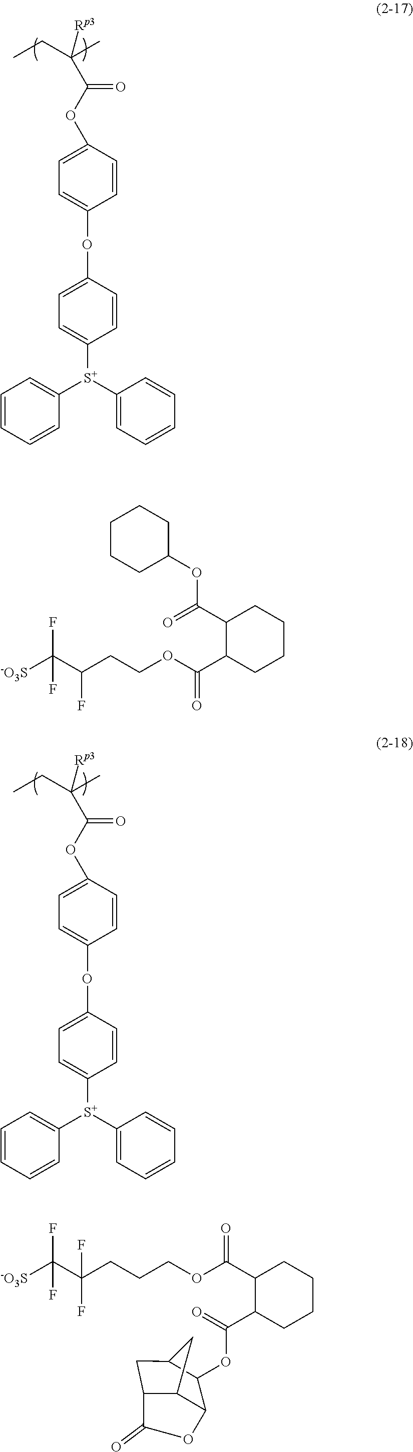

wherein R^{p3} is the same as defined for the formula (2).

Among these, the structural units represented by the formulas (2-3), (2-10), (2-11), and (2-12) are preferable.

The structural unit (I) represented by the formula (2) is configured so that the anion represented by X⁻ dissociates from the polymer chain upon exposure, and functions as an acid.

Examples of a monomer compound that produces the structural unit represented by the formula (2) include a compound represented by the following formula (2′), and the like.

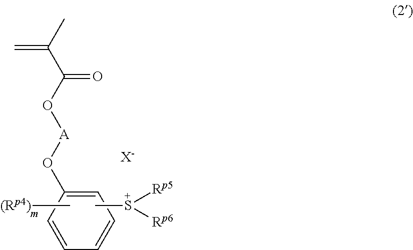

wherein A, R^{p4}, R^{p5}, R^{p6}, and X⁻ are the same as defined for the formula (2).

Examples of the compound represented by the formula (2′) include the compounds represented by the following formulas (2′-1) to (2′-18), and the like.

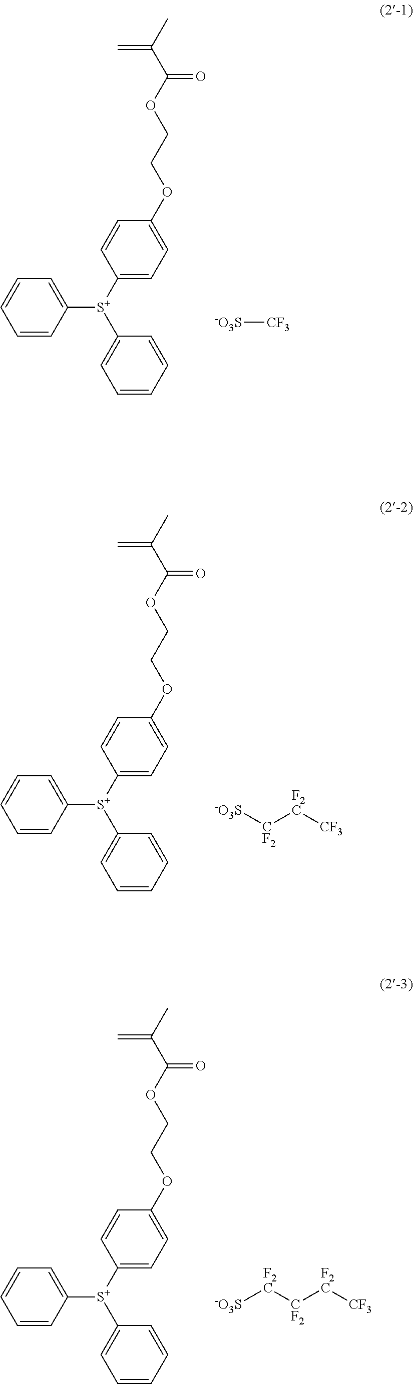

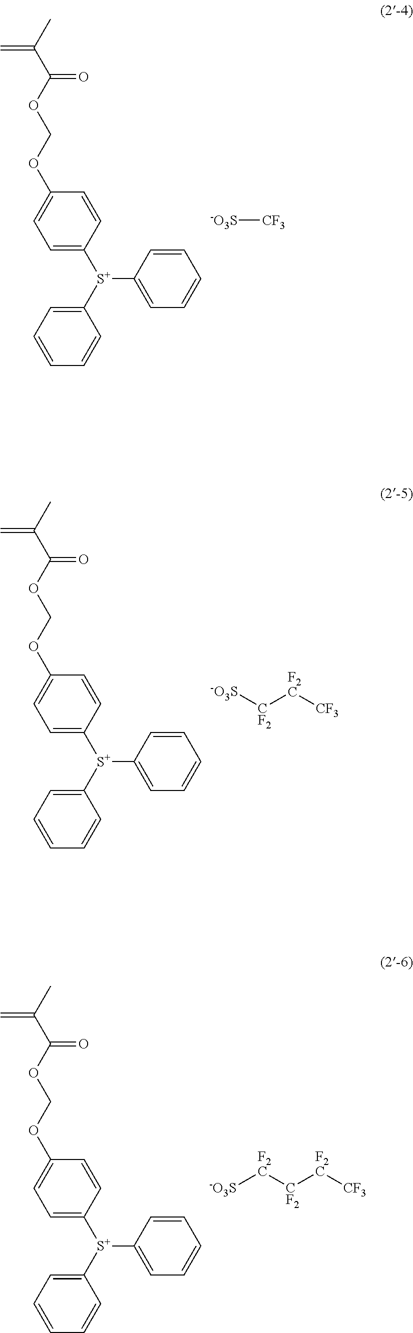

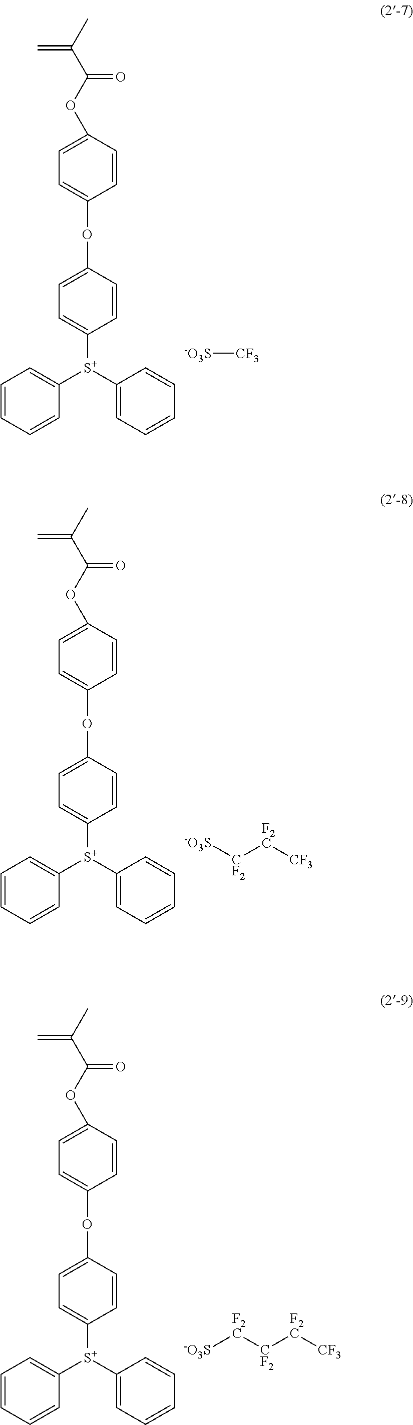

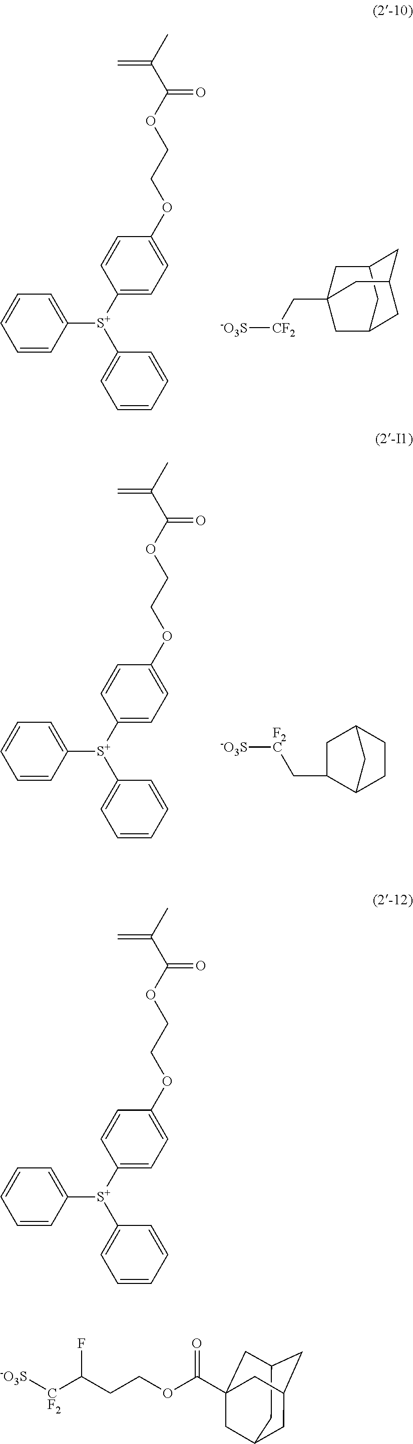

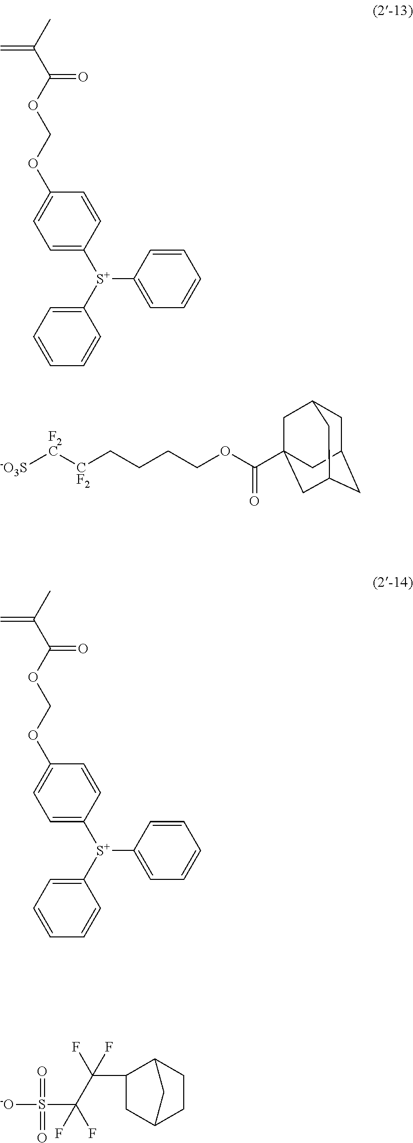

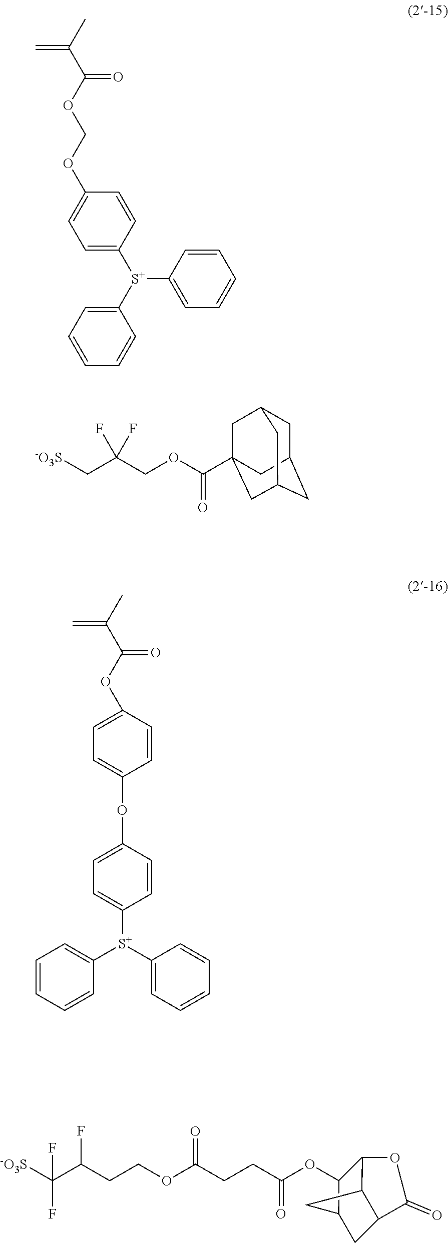

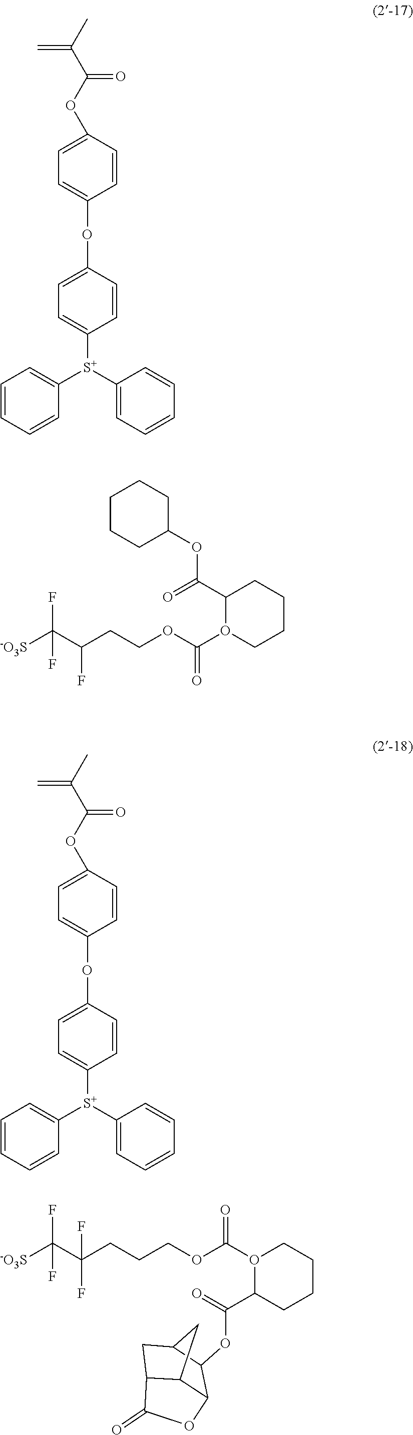

The content of the structural unit (I) in the polymer [A] is preferably 1 to 50 mol %, more preferably 1 to 30 mol %, and still more preferably 1 to 10 mol %, based on the total structural units included in the polymer [A]. When the content of the structural unit (I) is within the above range, the photoresist composition can effectively suppress occurrence of roughness, and form an excellent fine pattern. Note that the polymer [A] may include only one type of the structural unit (I), or may include two or more types of the structural unit (I).

### Structural Unit (II)

The polymer [A] preferably further includes the structural unit (II) represented by the formula (5). The structural unit (II) represented by the formula (5) is a structural unit in which the carbon atom that is bonded to the ester group is a tertiary carbon atom, and which includes an acid-labile group that easily dissociates due to an acid.

In the formula (5), R¹ is a hydrogen atom, a fluorine atom, a trifluoromethyl group, or an alkyl group having 1 to 3 carbon atoms, and R² to R⁴ are independently an alkyl group having 1 to 4 carbon atoms or an alicyclic hydrocarbon group having 4 to 20 carbon atoms, provided that R³ and R⁴ may bond to each other to form a divalent alicyclic hydrocarbon group having 4 to 20 carbon atoms together with the carbon atom to which R³ and R⁴ are bonded.

Examples of the alkyl group having 1 to 4 carbon atoms represented by R² to R⁴ include a methyl group, an ethyl group, an n-propyl group, an i-propyl group, an n-butyl group, a 2-methylpropyl group, a 1-methylpropyl group, a t-butyl group, and the like.

Examples of the alicyclic hydrocarbon group having 4 to 20 carbon atoms represented by R² to R⁴, or the alicyclic hydrocarbon group having 4 to 20 carbon atoms formed by R³ and R⁴ together with the carbon atom to which R³ and R⁴ are bonded, include polyalicyclic groups that include a bridged skeleton (e.g., adamantane skeleton or norbornane skeleton), and monoalicyclic groups that include a cycloalkane skeleton (e.g., cyclopentane skeleton or cyclohexane skeleton). These groups may be substituted with one or more linear, branched, or cyclic alkyl groups having 1 to 10 carbon atoms, for example.

Examples of the structural unit (II) include structural units represented by the following formulas, and the like.

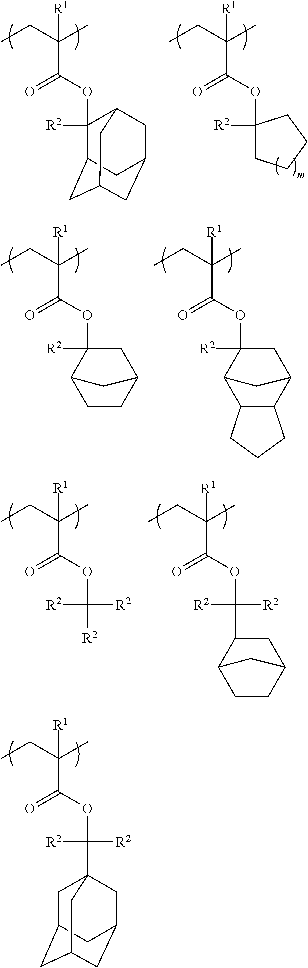

wherein R¹ is the same as defined for the formula (5), R² is an alkyl group having 1 to 4 carbon atoms, and m is an integer from 1 to 6.

Among these, the structural units represented by the following formulas (5-1) to (5-18) are preferable, and the structural units represented by the formulas (5-3), (5-4), (5-12), and (5-13) are more preferable.

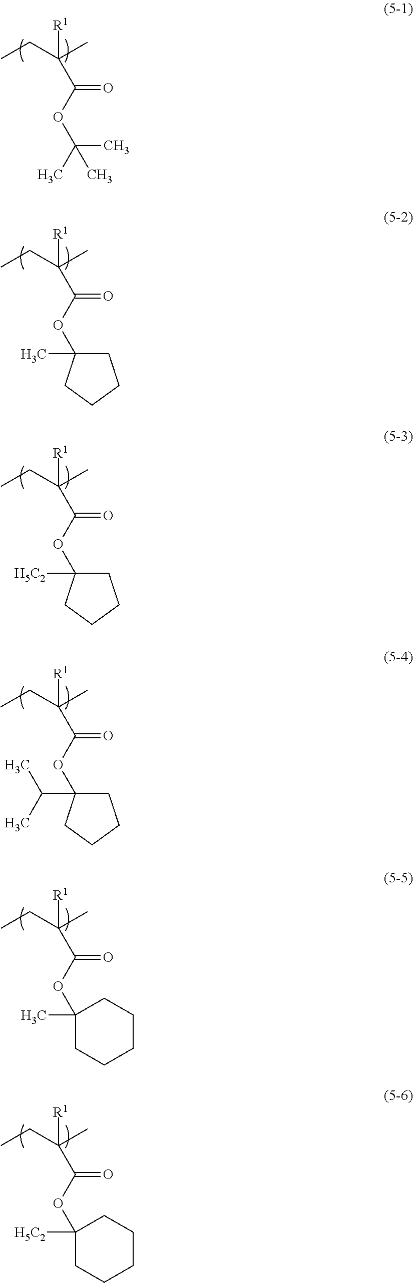

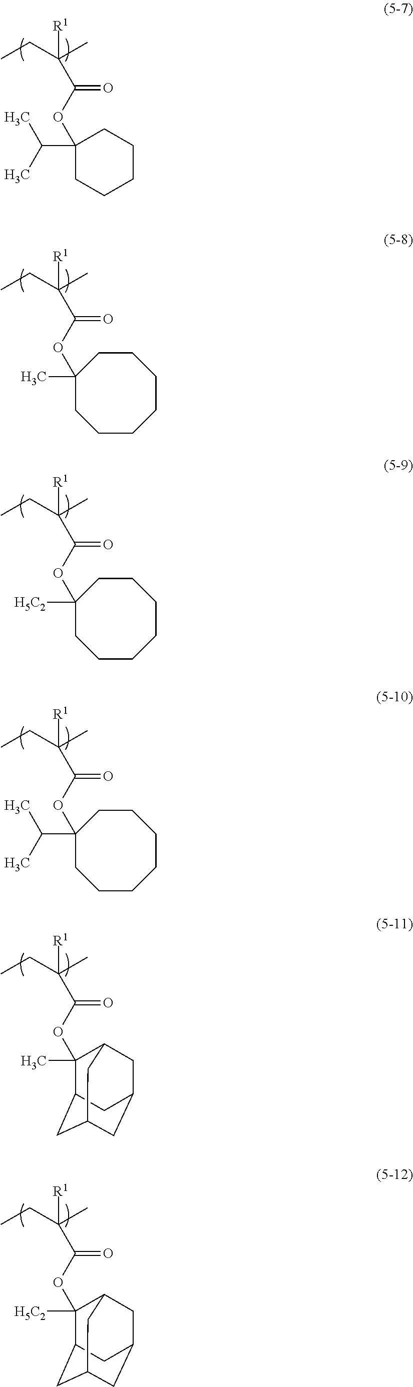

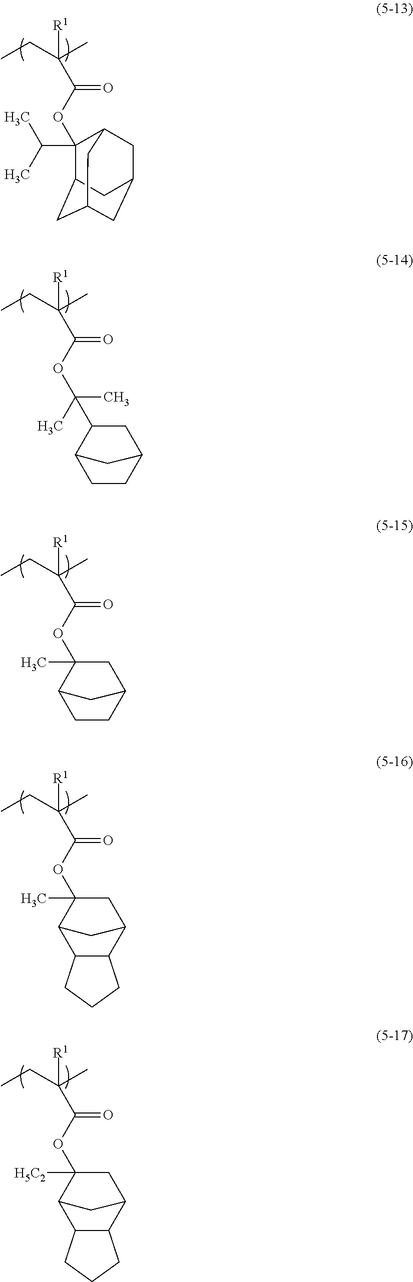

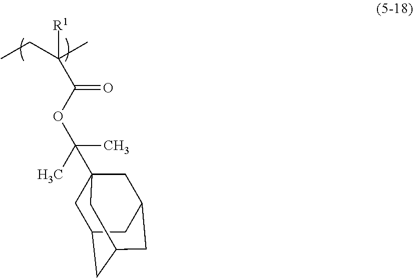

wherein R¹ is the same as defined for the formula (5).

The content of the structural unit (II) in the polymer [A] is preferably 10 to 80 mol %, and more preferably 20 to 60 mol %, based on the total structural units included in the polymer [A]. When the content of the structural unit (II) within the above range, the photoresist composition exhibits an excellent pattern-forming capability. Note that the polymer [A] may include only one type of the structural unit (II), or may include two or more types of the structural unit (II).

Examples of a monomer that produces the structural unit (II) include compounds represented by the following formulas, and the like.

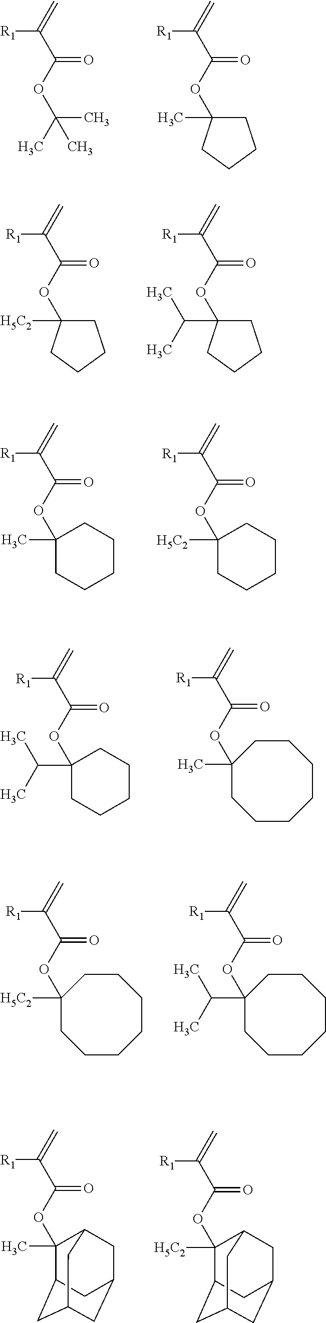

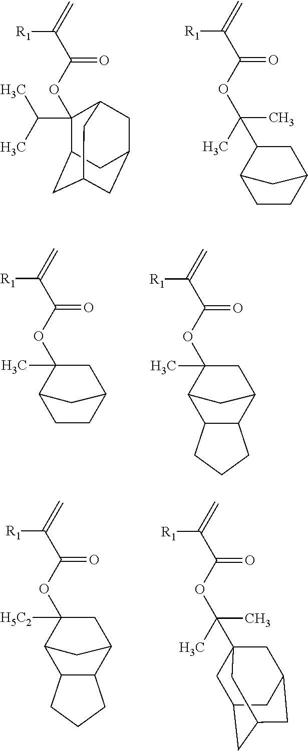

wherein R¹ is the same as defined for the formula (5).

### Structural Unit (III)

The polymer [A] may further include a structural unit (III) that includes a lactone skeleton or a cyclic carbonate skeleton as an additional structural unit. When the polymer [A] includes the structural unit (III), the photoresist composition exhibits improved adhesion to a substrate and the like.

Examples of the structural unit (III) include structural units represented by the following formulas, and the like.

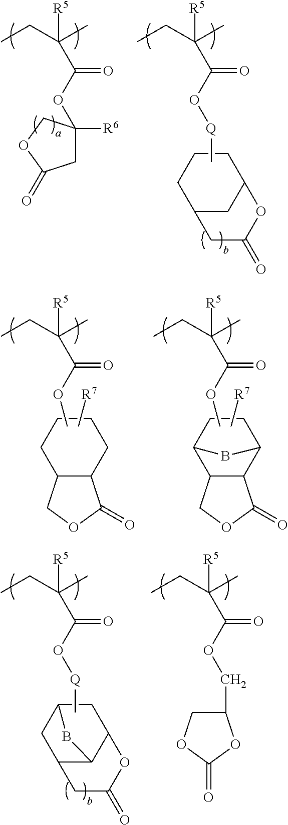

wherein R⁵ is a hydrogen atom, a fluorine atom, a trifluoromethyl group, or an alkyl group having 1 to 3 carbon atoms, R⁶ is a hydrogen atom or a methyl group, R⁷ is a hydrogen atom or a methoxy group, Q is a single bond or a methylene group, B is a methylene group or an oxygen atom, and a and b are 0 or 1.

Structural units represented by the following formulas are preferable as the structural unit (III).

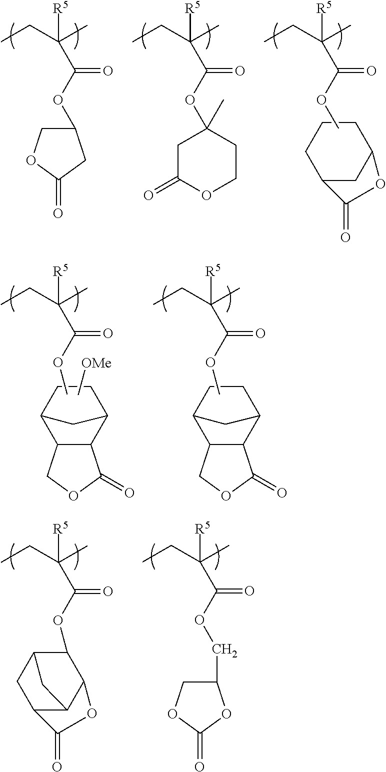

wherein R⁵ is a hydrogen atom or a methyl group.

The content of the structural unit (III) in the polymer [A] is preferably 0 to 70 mol %, and more preferably 10 to 60 mol %, based on the total structural units included in the polymer [A]. When the content of the structural unit (III) is within the above range, the photoresist composition exhibits improved adhesion to a substrate and the like.

Examples of a preferable monomer that produces the structural unit (III) include the monomers disclosed in WO2007/116664.

The polymer [A] may further include a structural unit (IV) that includes a polar group (see the following formulas). Examples of the polar group include a hydroxyl group, a carboxyl group, a keto group, a sulfonamide group, an amino group, an amide group, a cyano group, and the like. Note that the structural unit (IV) excludes a structural unit that includes an aromatic ring.

Examples of the structural unit (IV) include structural units represented by the following formulas.

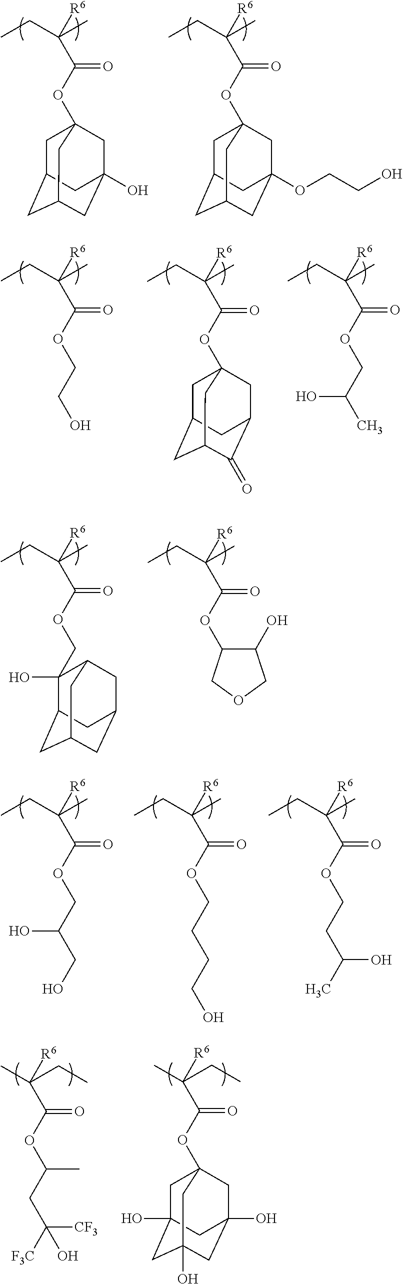

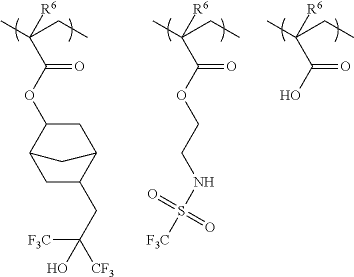

wherein R⁶ is a hydrogen atom, a fluorine atom, a trifluoromethyl group, or an alkyl group having 1 to 3 carbon atoms.

Examples of a monomer that produces the structural unit (IV) include the compounds represented by the following formulas, and the like.

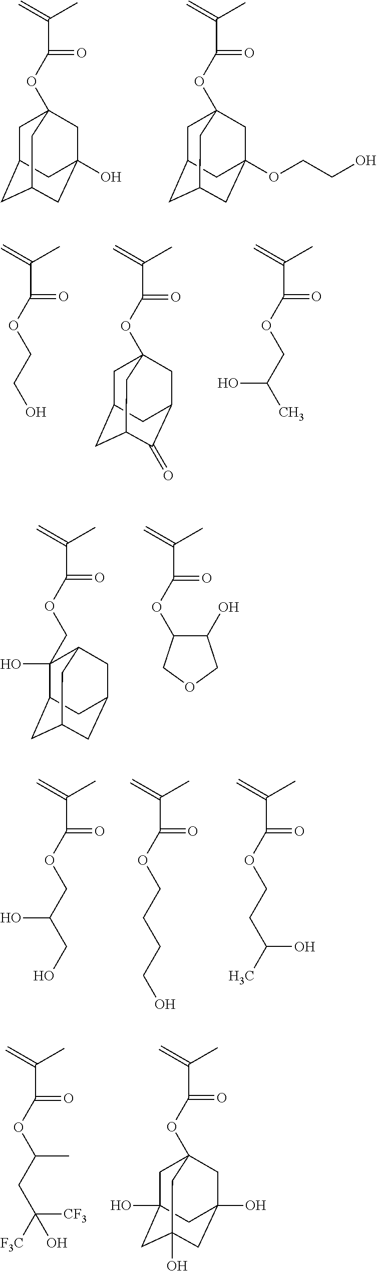

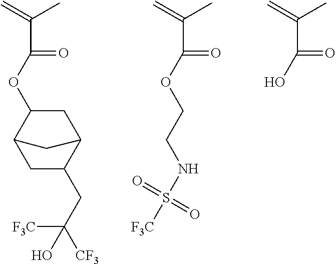

The content of the structural unit (IV) in the polymer [A] is preferably 5 to 80 mol %, and more preferably 10 to 40 mol %, based on the total structural units included in the polymer [A]. Note that the polymer [A] may include only one type of the structural unit (IV), or may include two or more types of the structural unit (IV).

The polymer [A] may include a structural unit (V) derived from an aromatic compound as an additional structural unit. Examples of the structural unit (V) include structural units represented by the following formulas, and the like.

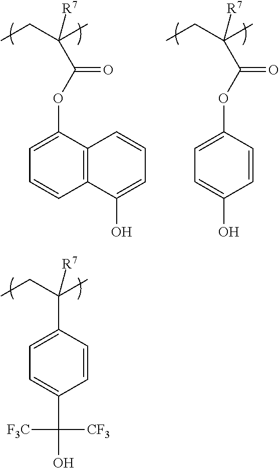

wherein R⁷ is a hydrogen atom, a fluorine atom, a trifluoromethyl group, or an alkyl group having 1 to 3 carbon atoms.

Examples of a preferable monomer that produces the structural unit (V) derived from an aromatic compound include styrene, α-methylstyrene, 2-methylstyrene, 3-methylstyrene, 4-methylstyrene, 2-methoxystyrene, 3-methoxystyrene, 4-methoxystyrene, 5-hydroxy-1-naphthyl(meth)acrylate, 4-hydroxyphenyl(meth)acrylate, 4-(2-hydroxy-1,1,1,3,3,3-hexafluoro)styrene, 4-(2-t-butoxycarbonylethyloxy)styrene, 2-hydroxystyrene, 3-hydroxystyrene, 4-hydroxystyrene, 2-hydroxy-α-methylstyrene, 3-hydroxy-α-methylstyrene, 4-hydroxy-α-methylstyrene, 2-methyl-3-hydroxystyrene, 4-methyl-3-hydroxystyrene, 5-methyl-3-hydroxystyrene, 2-methyl-4-hydroxystyrene, 3-methyl-4-hydroxystyrene, 3,4-dihydroxystyrene, 2,4,6-trihydroxystyrene, 4-t-butoxystyrene, 4-t-butoxy-α-methylstyrene, 4-(2-ethyl-2-propoxy)styrene, 4-(2-ethyl-2-propoxy)-α-methylstyrene, 4-(1-ethoxyethoxy)styrene, 4-(1-ethoxyethoxy)-α-methylstyrene, phenyl(meth)acrylate, benzyl(meth)acrylate, acenaphthylene, 5-hydroxyacenaphthylene, 1-vinylnaphthalene, 2-vinylnaphthalene, 2-hydroxy-6-vinylnaphthalene, 1-naphthyl(meth)acrylate, 2-naphthyl(meth)acrylate, 1-naphthylmethyl(meth)acrylate, 1-anthryl(meth)acrylate, 2-anthryl(meth)acrylate, 9-anthryl(meth)acrylate, 9-anthrylmethyl(meth)acrylate, 1-vinylpyrene, and the like.

The content of the structural unit (V) in the polymer [A] is preferably 5 to 50 mol %, and more preferably 10 to 30 mol %, based on the total structural units included in the polymer [A]. Note that the polymer [A] may include only one type of the structural unit (V), or may include two or more types of the structural unit (V).

### Synthesis of Polymer [A]

The polymer [A] may be produced by polymerizing a monomer that produces each structural unit in an appropriate solvent using a radical initiator, for example. The polymer [A] is preferably produced by adding a solution containing a monomer and a radical initiator dropwise to a reaction solvent or a solution containing a monomer to effect polymerization, or adding a solution containing a monomer and a solution containing a radical initiator dropwise to a reaction solvent or a solution containing a monomer to effect polymerization, or adding a plurality of solutions containing a different monomer and a solution containing a radical initiator dropwise to a reaction solvent or a solution containing a monomer to effect polymerization, for example.

Examples of the solvent used for polymerization include alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutanes, bromohexanes, dichloroethanes, hexamethylene dibromide, and chlorobenzene; saturated carboxylates such as ethyl acetate, n-butyl acetate, i-butyl acetate, and methyl propionate; ketones such as acetone, 2-butanone, 4-methyl-2-pentanone, and 2-heptanone; ethers such as tetrahydrofuran, dimethoxyethanes, and diethoxyethanes; alcohols such as methanol, ethanol, 1-propanol, 2-propanol, and 4-methyl-2-pentanol; and the like. These solvents may be used either alone or in combination.

The reaction temperature may be appropriately determined depending on the type of radical initiator, but is normally 40 to 150° C., and preferably 50 to 120° C. The reaction time is normally 1 to 48 hours, and preferably 1 to 24 hours.

Examples of the radical initiator used for polymerization include azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis (2 methylpropionitrile), and the like. These initiators may be used either alone or in combination.

The polymer obtained by polymerization is preferably collected by reprecipitation. Specifically, the polymer solution is poured into a reprecipitation solvent after completion of polymerization to collect the target resin as a powder. An alcohol, an alkane, or the like may be used as the reprecipitation solvent either alone or in combination. The polymer may also be collected by removing low-molecular-weight components (e.g., monomer and oligomer) by a separation operation, a column operation, ultrafiltration, or the like.

The polystyrene-reduced weight average molecular weight (Mw) of the polymer [A] determined by gel permeation chromatography (GPC) is not particularly limited, but is preferably 1000 to 100,000, more preferably 1000 to 50,000, and particularly preferably 1000 to 30,000. When the Mw of the polymer [A] is within the above range, a resist formed using the photoresist composition exhibits excellent heat resistance, developability, and the like, so that a satisfactory pattern can be formed.

The ratio (Mw/Mn) of the Mw to the polystyrene-reduced number average molecular weight (Mn) of the polymer [A] determined by GPC is normally 1 to 5, preferably 1 to 3, and more preferably 1 to 2. When the ratio (Mw/Mn) of the polymer [A] is within the above range, the resulting photoresist film exhibits excellent resolution.

Note that the terms “polystyrene-reduced weight average molecular weight (Mw)” and “polystyrene-reduced number average molecular weight (Mn)” used herein refer to values determined by GPC using GPC columns (manufactured by Tosoh Corporation, G2000HXL×2, G3000HXL×1, G4000HXL×1) at a flow rate of 1.0 ml/min and a column temperature of 40° C. (eluant: tetrahydrofuran, standard: monodisperse polystyrene).

### Polymer [B]

It is preferable that the photoresist composition further include the polymer [B]. The polymer [B] does not include the structural unit (I) having an acid-generating capability, but includes the structural unit (II) represented by the formula (5) that includes an acid-labile group. The acid-labile group included in the polymer [B] dissociates due to an acid generated in the polymer [A] upon exposure, and the polymer [B] become insoluble in a developer that includes an organic solvent. This makes it possible to form a pattern that exhibits excellent contrast between the exposed area and the unexposed area.

The details of the structural unit (II) included in the polymer [B] are the same as the structural unit (II) that is preferably included in the polymer [A]. Therefore, detailed description thereof is omitted.

The content of the structural unit (II) in the polymer [B] is preferably 5 to 80 mol %, and more preferably 10 to 40 mol %, based on the total structural units included in the polymer [B]. Note that the polymer [B] may include only one type of the structural unit (II), or may include two or more types of the structural unit (II).

The polymer [B] may include a structural unit (III) that includes a lactone skeleton or a cyclic carbonate skeleton, a structural unit (IV) that includes a polar group, a structural unit (V) derived from an aromatic compound, and the like as additional structural units in addition to the structural unit (II). The description given above in connection with the structural units (III) to (V) that may be included in the polymer [A] is applied to the structural units (III) to (V).

The content of the structural unit (III) in the polymer [B] is preferably 5 to 70 mol %, and more preferably 10 to 60 mol %, based on the total structural units included in the polymer [B]. When the content of the structural unit (III) is within the above range, the photoresist composition exhibits improved adhesion to a substrate and the like.

The content of the structural unit (IV) in the polymer [B] is preferably 0 to 80 mol %, and more preferably 10 to 40 mol %, based on the total structural units included in the polymer [B]. Note that the polymer [B] may include only one type of the structural unit (IV), or may include two or more types of the structural unit (IV).

The content of the structural unit (V) in the polymer [B] is preferably 0 to 80 mol %, and more preferably 10 to 40 mol %, based on the total structural units included in the polymer [B]. Note that the polymer [B] may include only one type of the structural unit (V), or may include two or more types of the structural unit (V).

### Synthesis of Polymer [B]

The polymer [B] may be produced by polymerizing a monomer that produces each structural unit in an appropriate solvent using a radical initiator, for example.

Examples of the radical initiator and the solvent used for polymerization include those mentioned above in connection with synthesis of the polymer [A].

The Mw of the polymer [B] determined by GPC is preferably 1000 to 100,000, more preferably 1000 to 50,000, and particularly preferably 1000 to 30,000. When the Mw of the polymer [B] within the above range, the photoresist composition exhibits excellent lithographic performance.

The ratio (Mw/Mn) of the Mw to the Mn of the polymer [B] is normally 1 to 3, and preferably 1 to 2.

### Acid Generator [C]

The photoresist composition may further include the acid generator [C]. When the photoresist composition includes the acid generator [C] in combination with the polymer [A] that includes the structural unit (I) having an acid-generating capability, the photoresist composition exhibits improved sensitivity, and the amount of acid generated at an identical dose increases. The acid-labile group included in the polymer [A] and/or the polymer [B] dissociates due to the acid, and the exposed area becomes insoluble in a developer that includes an organic solvent. Note that the photoresist composition includes the acid generator [C] in the form of a compound (described below). The acid generator [C] excludes the polymer [A].

Examples of the acid generator [C] include onium salt compounds such as sulfonium salts and iodonium salts, organic halogen compounds, and sulfone compounds such as disulfones and diazomethanesulfones. Examples of the sulfonium salts include the compounds disclosed in paragraphs [0080] to [0113] of Japanese Patent Application Publication (KOKAI) No. 2009-134088, and the like.

Specific examples of a preferable acid generator [C] include diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, triphenylsulfonium trifluoromethanesulfonate, triphenylsulfonium nonafluoro-n-butanesulfonate,
triphenylsulfonium perfluoro-n-octanesulfonate,
cyclohexyl.2-oxocyclohexyl.methylsulfonium trifluoromethanesulfonate,
dicyclohexyl.2-oxocyclohexylsulfonium trifluoromethanesulfonate,
2-oxocyclohexyldimethylsulfonium trifluoromethanesulfonate,
4-hydroxy-1-naphthyldimethylsulfonium trifluoromethanesulfonate, triphenylsulfonium
6-(adamantylcarbonyloxy)-1,1,2,2-tetrafluorohexanesulfonate,
4-hydroxy-1-naphthyltetrahydrothiophenium trifluoromethanesulfonate,
4-hydroxy-1-naphthyltetrahydrothiophenium nonafluoro-n-butanesulfonate,
4-hydroxy-1-naphthyltetrahydrothiophenium perfluoro-n-octanesulfonate,
1-(1-naphthylacetomethyl)tetrahydrothiophenium trifluoromethanesulfonate,
1-(1-naphthylacetomethyl)tetrahydrothiophenium nonafluoro-n-butanesulfonate,
1-(1-naphthylacetomethyl)tetrahydrothiophenium perfluoro-n-octanesulfonate,
1-(3,5-dimethyl-4-hydroxyphenyl)tetrahydrothiophenium trifluoromethanesulfonate,
1-(3,5-dimethyl-4-hydroxyphenyl)tetrahydrothiophenium nonafluoro-n-butanesulfonate,
1-(3,5-dimethyl-4-hydroxyphenyl)tetrahydrothiophenium perfluoro-n-octanesulfonate,
trifluoromethanesulfonylbicyclo[2.2.1]hept-5-ene-2,3-dicarbodiimide,
nonafluoro-n-butanesulfonylbicyclo[2.2.1]hept-5-ene-2,3-dicarbodiimide,
perfluoro-n-octanesulfonylbicyclo[2.2.1]hept-5-ene-2,3-dicarbodiimide,
N-hydroxysuccinimidetrifluoromethanesulfonate,
N-hydroxysuccinimidenonafluoro-n-butanesulfonate,
N-hydroxysuccinimideperfluoro-n-octanesulfonate, and 1,8-naphthalenedicarboxylic acid imide trifluoromethanesulfonate.

These acid generators [C] may be used either alone or in combination. The acid generator [C] is normally used in an amount of 0.1 to 20 parts by mass, and preferably 0.5 to 10 parts by mass, based on 100 parts by mass of the polymer [A], from the viewpoint of ensuring that the resulting resist exhibits sufficient sensitivity and developability. If the amount of the acid generator [C] is less than 0.1 parts by mass, the resulting resist may exhibit insufficient sensitivity and developability. If the amount of the acid generator [C]exceeds 10 parts by mass, the desired resist pattern may not be obtained due to a decrease in transparency to exposure light.

### Fluorine-Containing Polymer [D]

The photoresist composition may include [D] a fluorine-containing polymer that is other than the polymer [A] and the polymer [B], and has a fluorine atom content higher than that of the polymer [A] and the polymer [B] (hereinafter may be referred to as “polymer [D]”). When the photoresist composition includes the polymer [D], the polymer [D] tends to be unevenly distributed in the surface area of a resist film formed using the photoresist composition due to the oil repellency of the polymer [D], and elution of the acid generator, an acid diffusion controller, and the like into an immersion medium during liquid immersion lithography can be suppressed. It is also possible to control the advancing contact angle of the resist film with the immersion medium within the desired range due to the water repellency of the polymer [D], and suppress occurrence of bubble defects. Moreover, since the receding contact angle of the resist film with the immersion medium increases (i.e., water droplets do not remain), it is possible to implement high-speed scan exposure. A resist film that is suitable for liquid immersion lithography can be formed by incorporating the polymer [D] in the photoresist composition.

The polymer [D] is produced by polymerizing one or more monomers that include a fluorine atom in the structure.

Examples of a structural unit included in the polymer [D] include a structural unit represented by the following formula, and the like.

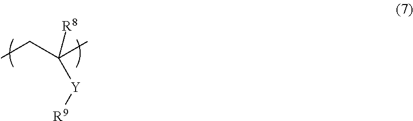

wherein R⁸ is a hydrogen atom, a fluorine atom, a trifluoromethyl group, or an alkyl group having 1 to 3 carbon atoms, Y is a linking group, and R⁹ is a linear or branched alkyl group having 1 to 6 carbon atoms that includes at least one fluorine atom, a monovalent alicyclic hydrocarbon group having 4 to 20 carbon atoms, or a derivative thereof.

Examples of the linking group represented by Y include a single bond, an oxygen atom, a sulfur atom, a carbonyloxy group, an oxycarbonyl group, an amide group, a sulfonylamide group, a urethane group, and the like.

The polymer [D] may further include one or more additional structural units described in detail above in connection with the polymer [D], such as the structural unit (II) that includes an acid-labile group and controls the dissolution rate in a developer, the structural unit (III) that includes a lactone skeleton or a cyclic carbonate skeleton, the structural unit (IV) that includes a polar group, and the structural unit (V) that is derived from an aromatic compound and suppresses scattering of light due to reflection from a substrate.

The Mw of the polymer [D] is preferably 1000 to 100,000, more preferably 1000 to 50,000, and still more preferably 1000 to 30,000. If the Mw of the polymer [D] is less than 1000, a sufficient receding contact angle may not be obtained. If the Mw of the polymer [D] exceeds 50,000, the resulting resist may exhibit insufficient developability. The ratio (Mw/Mn) of the Mw to the Mn of the polymer [D] is normally 1 to 3, and preferably 1 to 2.

The polymer [D] is preferably used in an amount of 0 to 50 parts by mass, more preferably 0 to 20 parts by mass, still more preferably 0.5 to 10 parts by mass, and particularly preferably 1 to 8 parts by mass, based on 100 parts by mass of the polymer [A]. When the amount of the polymer [D] is within the above range, the water repellency and the elution resistance of the surface of the resulting resist film can be further improved.

### Synthesis of Polymer [D]

The polymer [D] may be synthesized by polymerizing a monomer that produces each structural unit in an appropriate solvent using a radical initiator, for example.

Examples of the radical initiator and the solvent used for polymerization include those mentioned above in connection with synthesis of the polymer [A].

### Nitrogen-Containing Compound [E]

It is preferable that the photoresist composition further include [E] a nitrogen-containing compound. The nitrogen-containing compound [E] controls a phenomenon in which the acid generated by the structural unit (I) (that is included in the polymer [A] and has an acid-generating capability) and the acid generator [C] upon exposure diffuses in the resist film to improve the resolution of the resulting resist, and improves the storage stability of the photoresist composition. The nitrogen-containing compound [E] may be included in the photoresist composition in the form of a free compound, and/or may be included in an arbitrary polymer.

Examples of the nitrogen-containing compound [E] include a compound represented by the following formula.

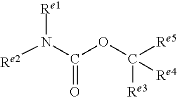

wherein R^{e2} to R^{e5} are independently a hydrogen atom, a linear, branched, or cyclic alkyl group having 1 to 20 carbon atoms, an aryl group, or an aralkyl group, provided that these groups may be substituted with a substituent, R^{e1} and R^{e2} may bond to each other to form a divalent saturated or unsaturated hydrocarbon group having 4 to 20 carbon atoms, or a derivative thereof, together with the nitrogen atom to which R^{e1} and R^{e2} are bonded, and/or R^{e3} and R^{e4} may bond to each other to form a divalent saturated or unsaturated hydrocarbon group having 4 to 20 carbon atoms, or a derivative thereof, together with the carbon atom to which R^{e3} and R^{e4} are bonded.

Examples of the nitrogen-containing compound [E] represented by the above formula include N-t-alkylalkoxycarbonyl group-containing amino compounds such as
N-t-butoxycarbonyldi-n-octylamine, N-t-amyloxycarbonyldi-n-octylamine,
N-t-butoxycarbonyldi-n-nonylamine, N-t-amyloxycarbonyldi-n-nonylamine,
N-t-butoxycarbonyldi-n-decylamine, N-t-amyloxycarbonyldi-n-decylamine,
N-t-butoxycarbonyldicyclohexylamine, N-t-amyloxycarbonyldicyclohexylamine,
N-t-butoxycarbonyl-1-adamantylamine, N-t-amyloxycarbonyl-1-adamantylamine,
N-t-butoxycarbonyl-2-adamantylamine, N-t-amyloxycarbonyl-2-adamantylamine,
N-t-butoxycarbonyl-N-methyl-1-adamantylamine,
N-t-amyloxycarbonyl-N-methyl-1-adamantylamine,
(S)-(−)-1-(t-butoxycarbonyl)-2-pyrrolidinemethanol,
(S)-(−)-1-(t-amyloxycarbonyl)-2-pyrrolidinemethanol,
(R)-(+)-1-(t-butoxycarbonyl)-2-pyrrolidinemethanol,
(R)-(+)-1-(t-amyloxycarbonyl)-2-pyrrolidinemethanol,
N-t-butoxycarbonyl-4-hydroxypiperidine, N-t-amyloxycarbonyl-4-hydroxypiperidine,
N-t-butoxycarbonylpyrrolidine, N-t-amyloxycarbonylpyrrolidine,
N,N′-di-t-butoxycarbonylpiperazine, N,N′-di-t-amyloxycarbonylpiperazine,
N,N-di-t-butoxycarbonyl-1-adamantylamine, N,N-di-t-amyloxycarbonyl-1-adamantylamine,
N-t-butoxycarbonyl-4,4′-diaminodiphenylmethane,
N-t-amyloxycarbonyl-4,4′-diaminodiphenylmethane,
N,N′-di-t-butoxycarbonylhexamethylenediamine,
N,N′-di-t-amyloxycarbonylhexamethylenediamine,
N,N,N′,N′-tetra-t-butoxycarbonylhexamethylenediamine,
N,N,N′,N′-tetra-t-amyloxycarbonylhexamethylenediamine,
N,N′-di-t-butoxycarbonyl-1,7-diaminoheptane,
N,N′-di-t-amyloxycarbonyl-1,7-diaminoheptane,
N,N′-di-t-butoxycarbonyl-1,8-diaminooctane, N,N′-di-t-amyloxycarbonyl-1,8-diaminooctane,
N,N′-di-t-butoxycarbonyl-1,9-diaminononane,
N,N′-di-t-amyloxycarbonyl-1,9-diaminononane,
N,N′-di-t-butoxycarbonyl-1,10-diaminodecane,
N,N′-di-t-amyloxycarbonyl-1,10-diaminodecane,
N,N′-di-t-butoxycarbonyl-1,12-diaminododecane,
N,N′-di-t-amyloxycarbonyl-1,12-diaminododecane,
N,N′-di-t-butoxycarbonyl-4,4′-diaminodiphenylmethane,
N,N′-di-t-amyloxycarbonyl-4,4′-diaminodiphenylmethane,
N-t-butoxycarbonylbenzimidazole, N-t-butoxycarbonylbenzimidazole,
N-t-amyloxycarbonyl-2-methylbenzimidazole, N-t-butoxycarbonyl-2-phenylbenzimidazole, and N-t-amyloxycarbonyl-2-phenylbenzimidazole, and the like.

Further examples of the nitrogen-containing compound [E] include tertiary amine compounds, quaternary ammonium hydroxide compounds, photodegradable base compounds, nitrogen-containing heterocyclic compounds, and the like.

Examples of the tertiary amine compounds include tri(cyclo)alkylamines such as triethylamine, tri-n-propylamine, tri-n-butylamine, tri-n-pentylamine, tri-n-hexylamine, tri-n-heptylamine, tri-n-octylamine, cyclohexyldimethylamine, dicyclohexylmethylamine, and tricyclohexylamine, aromatic amines such as aniline, N-methylaniline, N,N-dimethylaniline, 2-methylaniline, 3-methylaniline, 4-methylaniline, 4-nitroaniline, 2,6-dimethylaniline, and 2,6-diisopropylaniline, alkanolamines such as triethanolamine and N,N-di(hydroxyethyl)aniline, N,N,N′,N′-tetramethylethylenediamine, N,N,N′,N′-tetrakis(2-hydroxypropyl)ethylenediamine, 1,3-bis[1-(4-aminophenyl)-1-methylethyl]benzenetetramethylenediamine, bis(2-dimethylaminoethyl)ether, bis(2-diethylaminoethyl)ether, and the like.

Examples of the quaternary ammonium hydroxide compounds include tetra-n-propylammonium hydroxide, tetra-n-butylammonium hydroxide, and the like.

Examples of the photo degradable base compounds include sulfonium salt compounds represented by the following formula (8-1), iodonium salt compounds represented by the following formula (8-2), and the like.

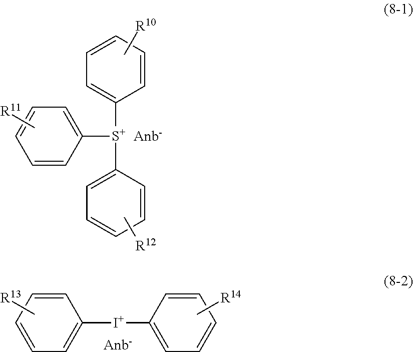

wherein R¹⁰ to R¹⁴ are independently a hydrogen atom, an alkyl group, an alkoxy group, a hydroxyl group, or a halogen atom, and Anb⁻ is OH⁻, R¹⁵COO⁻, R¹⁵—SO₃⁻ (wherein R¹⁵ is an alkyl group, an aryl group, or an alkanol group), or an anion represented by the following formula (9).

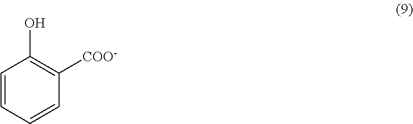

Specific examples of the sulfonium salt compounds and the iodonium salt compounds include triphenylsulfonium hydroxide, triphenylsulfonium acetate, triphenylsulfonium salicylate, diphenyl-4-hydroxyphenylsulfonium hydroxide, diphenyl-4-hydroxyphenylsulfonium acetate, diphenyl-4-hydroxyphenylsulfonium salicylate, bis(4-t-butylphenyl)iodonium hydroxide, bis(4-t-butylphenyl)iodonium acetate, bis(4-t-butylphenyl)iodonium hydroxide, bis(4-t-butylphenyl)iodonium acetate, bis(4-t-butylphenyl)iodonium salicylate, 4-t-butylphenyl-4-hydroxyphenyliodonium hydroxide, 4-t-butylphenyl-4-hydroxyphenyliodonium acetate, 4-t-butylphenyl-4-hydroxyphenyliodonium salicylate, bis(4-t-butylphenyl)iodonium 10-camphorsulfonate, diphenyliodonium 10-camphorsulfonate, triphenylsulfonium 10-camphorsulfonate, 4-t-butoxyphenyldiphenylsulfonium 10-camphorsulfonate, and the like.

The nitrogen-containing compound [E] is preferably used in an amount of 10 parts by mass or less, and more preferably 8 parts by mass or less, based on 100 parts by mass of the polymer [A]. If the amount of the nitrogen-containing compound [E] exceeds 10 parts by mass, the sensitivity of the resulting resist may deteriorate.

### Solvent [F]

The photoresist composition normally includes the solvent [F]. Examples of the solvent [F] include alcohol-based solvents, ketone-based solvents, amide-based solvents, ether-based solvents, ester-based solvents, a mixed solvent thereof, and the like.

Examples of the alcohol-based solvents include monohydric alcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, t-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; polyhydric alcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; polyhydric alcohol partial ether-based solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethyl butyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropyleneglycol monomethylether, dipropylene glycol monoethyl ether, and dipropylene glycol monopropyl ether; and the like.

Examples of the ketone-based solvents include acetone, methyl ethyl ketone, methyl n-propyl ketone, methyl n-butyl ketone, diethyl ketone, methyl isobutyl ketone, methyl n-pentyl ketone, ethyl n-butyl ketone, methyl n-hexyl ketone, diisobutyl ketone, trimethylenonane, cycloheptanone, cyclohexanone, cycloheptanone, cyclooctanone, methylcyclohexanone, 2,4-pentanedione, acetonylacetone, diacetone alcohol, acetophenone, and the like.

Examples of the amide-based solvents include N,N′-dimethylimidazolidinone, N-methylformamide, N,N-dimethylformamide, N,N-diethylformamide, acetamide, N-methylacetamide, N,N-dimethylacetamide, N-methylpropioneamide, N-methylpyrrolidone, and the like.

Examples of the ester-based solvents include diethyl carbonate, propylene carbonate, methyl acetate, ethyl acetate, γ-butyrolactone, γ-valerolactone, n-propyl acetate, isopropyl acetate, n-butyl acetate, isobutyl acetate, sec-butyl acetate, n-pentyl acetate, sec-pentyl acetate, isoamyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, isoamyl propionate, diethyl oxalate, di-n-butyl oxalate, methyl lactate, ethyl lactate, n-butyl lactate, n-amyl lactate, diethyl malonate, dimethyl phthalate, diethyl phthalate, and the like.

Further examples of the solvent [F] include aliphatic hydrocarbon-based solvents such as n-pentane, isopentane, n-hexane, isohexane, n-heptane, isoheptane, 2,2,4-trimethylpentane, n-octane, isooctane, cyclohexane, and methylcyclohexane; aromatic hydrocarbon-based solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, n-amylnaphthalene, and anisole; halogen-containing solvents such as dichloromethane, chloroform, fluorocarbon, chlorobenzene, and dichlorobenzene; and the like.

Among these, propylene glycol monomethyl ether acetate, propylene glycol monomethyl ether, ethyl lactate, γ-butyrolactone, and cyclohexanone are preferable.

### Additional Optional Component

The photoresist composition may include an uneven distribution promoter, an alicyclic skeleton-containing compound, a surfactant, a sensitizer, and the like as long as the advantageous effects of the invention are not impaired. Each additional optional component is described in detail below. Each additional optional component may be used either alone or in combination. The content of each additional optional component may be appropriately determined depending on the objective.

### Uneven Distribution Promoter

The photoresist composition may include the uneven distribution promoter when the photoresist composition is used to form a resist pattern using liquid immersion lithography, for example. When the photoresist composition includes the uneven distribution promoter, the polymer [D] can be more advantageously unevenly distributed in the vicinity of the surface area. Examples of the uneven distribution promoter include γ-butyrolactone, propylene carbonate, and the like.

### Alicyclic Skeleton-Containing Compound

The alicyclic skeleton-containing compound further improves the dry etching resistance, the pattern shape, adhesion to a substrate, and the like.

### Surfactant

The surfactant improves the applicability, striation, developability, and the like.

### Sensitizer

The sensitizer absorbs the energy of exposure light, and transmits the energy to the compound [A], so that the amount of acid generated increases. The sensitizer thus improves the apparent sensitivity of the photoresist composition.

### Preparation of Photoresist Composition

The photoresist composition may be prepared by mixing the polymer [A], the polymer [B] (preferable component), the acid generator [C] (preferable component), the polymer [D] (optional), the nitrogen-containing compound [E] (optional), and an additional optional component in the solvent [F] in a given ratio, for example. The photoresist composition is normally prepared by dissolving the components in the solvent [F] so that the total solid content is 1 to 50 mass %, and preferably 2 to 25 mass %, and filtering the solution through a filter having a pore size of about 0.2 for example.

### EXAMPLES

The invention is further described below by way of examples. Note that the invention is not limited to the following examples.

The Mw and the Mn of the polymer were determined under the following conditions using GPC columns manufactured by Tosoh Corporation (G2000HXL×2, G3000HXL×1, G4000HXL×1).

Column temperature: 40° C.
Eluant: tetrahydrofuran (LiBr: 0.3 mass %, H₃PO₄: 0.1 mass %, mixed solution)
Flow rate: 1.0 ml/min
Sample concentration: 0.2 mass %
Sample injection amount: 100 μl
Detector: differential refractometer
Standard: monodisperse polystyrene

The polymer was subjected to ¹H-NMR analysis and ¹³C-NMR analysis using a nuclear magnetic resonance spectrometer (“JNM-EX270” manufactured by JEOL Ltd.).

### Synthesis of Polymer [A] and Polymer [B]

The polymer [A], the polymer [B], and the polymer [D] were synthesized using the following monomers.

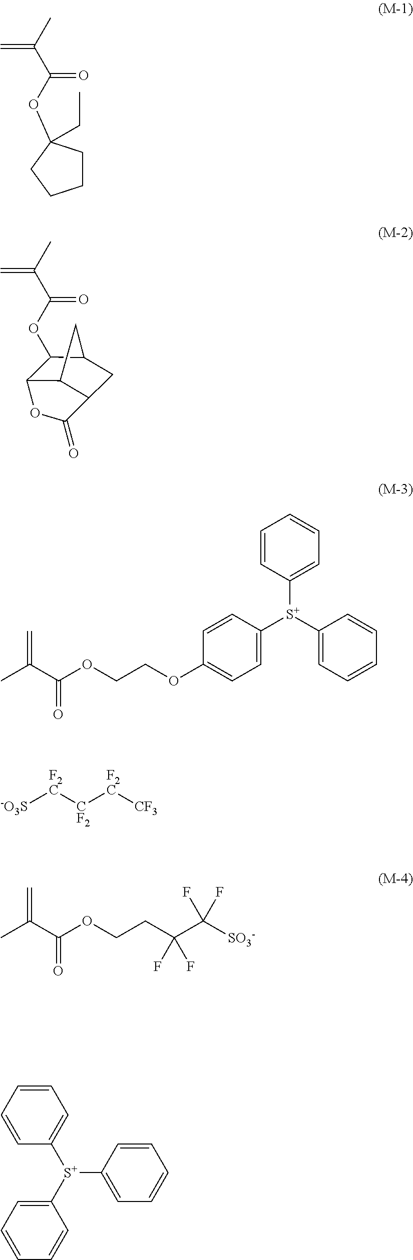

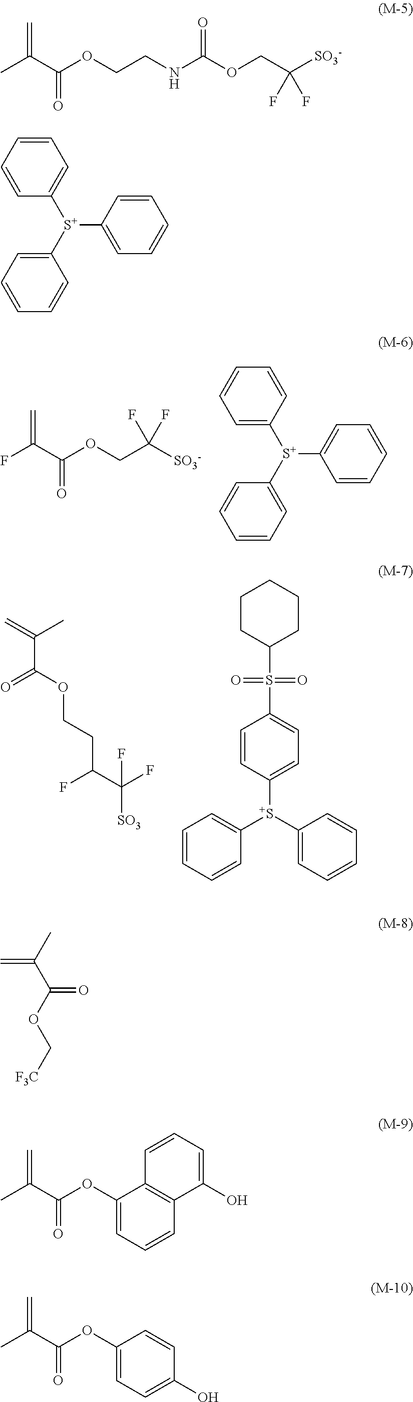

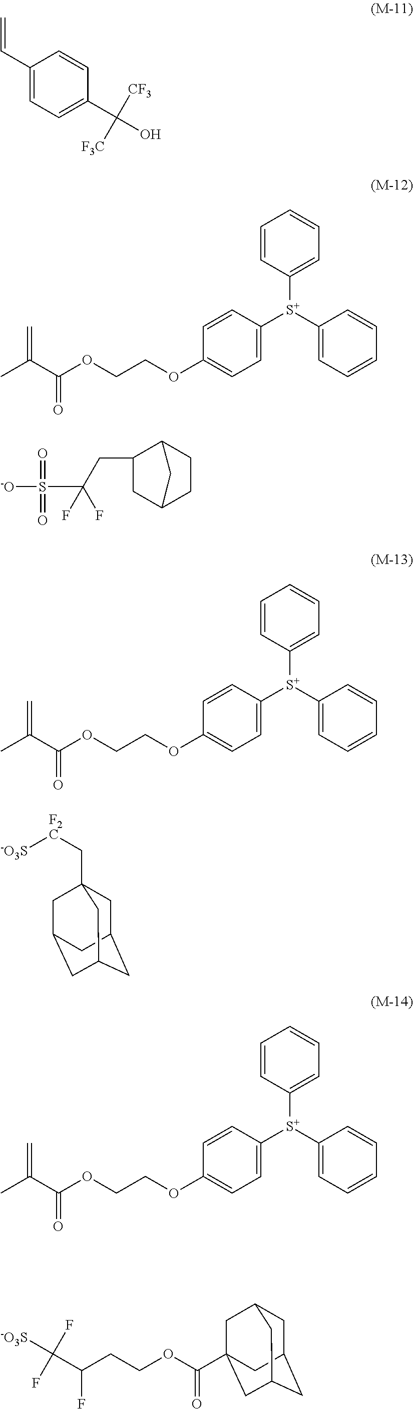

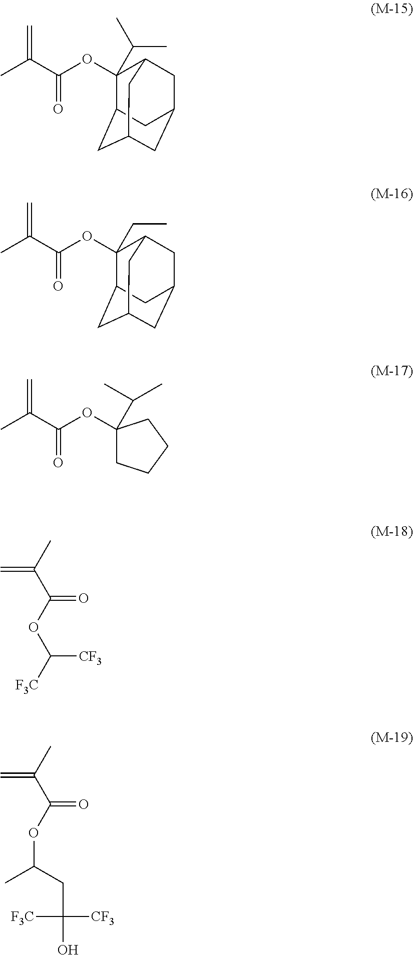 [SMILES: C=C(C)C(=O)OC1(C(C)C)C2CC3CC(C2)CC1C3 ; C=C(C)C(=O)OC1(CC)C2CC3CC(C2)CC1C3 ; C=C(C)C(=O)OC1(C(C)C)CCCC1 ; C=C(C)C(=O)OC(C(F)(F)F)C(F)(F)F ; C=C(C)C(=O)OC(C)CC(O)(C(F)(F)F)C(F)(F)F]

### Synthesis Example 1

11.8 g (46 mol %) of the compound (M-1), 2.3 g (3 mol %) of the compound (M-3), and 15.9 g (51 mol %) of the compound (M-2) were dissolved in 60 g of methyl ethyl ketone, and 1.2 g of AIBN was added to the solution to prepare a monomer solution. A three-necked flask (500 ml) was charged with 30 g of methyl ethyl ketone, purged with nitrogen for 30 minutes, and heated to 80° C. with stirring. The monomer solution was added dropwise to the flask over 3 hours using a dropping funnel. The monomers were polymerized for 6 hours from the start of dropwise addition of the monomer solution. After completion of polymerization, the polymer solution was cooled with water to 30° C. or less. The cooled polymer solution was added to 600 g of methanol or heptane, and a white powder that precipitated by this operation was filtered off. The white powder was washed twice with 120 g of methanol or isopropanol in a slurry state, filtered off, and dried at 50° C. for 17 hours to obtain a white powdery polymer (A-1) (polymer [A]) (25.4 g, yield: 84.5%). The polymer (A-1) had an Mw of 6900 and a dispersity (Mw/Mn) of 1.4. The ratio of the content of structural units derived from the compound (M-1), the content of structural units derived from the compound (M-3), and the content of structural units derived from the compound (M-2) in the polymer (A-1) (determined by ¹³C-NMR analysis) was 41.0:3.5:55.5 (mol %).

### Synthesis Examples 2 to 17

Polymers (A-2) to (A-15) (polymer [A]) and polymers (B-1) and (B-2) (polymer [B]) were obtained in the same manner as in Synthesis Example 1, except that the monomers shown in Table 1 were used in the amounts shown in Table 1. The Mw, the dispersity (Mw/Mn), and the yield (%) of each polymer, and the content of structural units derived from each monomer in each polymer are also shown in Table 1.

TABLE 1

| | | | | Content | | | |
|---|---|---|---|---|---|---|---|
| | | | | of | | Property | |
| | Polymer | Monomer | | structural | | value | |
| | [A] | | Amount | unit | Yield | | Mw/ |
| | or [B] | Type | (mol %) | (mol %) | (%) | Mw | Mn |
| Synthesis | (A-1) | M-1 | 46 | 41.0 | 84.5 | 6900 | 1.40 |
| Example 1 | | M-2 | 51 | 55.5 | | | |
| | | M-3 | 3 | 3.5 | | | |
| Synthesis | (A-2) | M-1 | 46 | 41.4 | 84.3 | 6700 | 1.39 |
| Example 2 | | M-2 | 51 | 55.3 | | | |
| | | M-4 | 3 | 3.3 | | | |
| Synthesis | (A-3) | M-1 | 46 | 41.7 | 82.4 | 6700 | 1.41 |
| Example 3 | | M-2 | 51 | 55.2 | | | |
| | | M-5 | 3 | 3.1 | | | |
| Synthesis | (A-4) | M-1 | 46 | 41.5 | 79.8 | 6900 | 1.42 |
| Example 4 | | M-2 | 51 | 55.3 | | | |
| | | M-6 | 3 | 3.2 | | | |
| Synthesis | (A-5) | M-1 | 46 | 41.3 | 79.6 | 7000 | 1.43 |
| Example 5 | | M-2 | 51 | 55.1 | | | |
| | | M-7 | 3 | 3.6 | | | |
| Synthesis | (A-6) | M-1 | 45 | 42.8 | 86.2 | 6700 | 1.58 |
| Example 6 | | M-2 | 35 | 37.2 | | | |
| | | M-7 | 6 | 6.3 | | | |
| | | M-9 | 14 | 13.7 | | | |
| Synthesis | (A-7) | M-1 | 45 | 42.4 | 84.3 | 6700 | 1.39 |
| Example 7 | | M-2 | 35 | 37.4 | | | |
| | | M-7 | 6 | 6.4 | | | |
| | | M-10 | 14 | 13.8 | | | |
| Synthesis | (A-8) | M-1 | 45 | 42.8 | 82.4 | 6700 | 1.41 |
| Example 8 | | M-2 | 35 | 37.4 | | | |
| | | M-7 | 6 | 6.1 | | | |
| | | M-11 | 14 | 13.7 | | | |
| Synthesis | (A-9) | M-1 | 46 | 42.0 | 78.5 | 7100 | 1.41 |
| Example 9 | | M-2 | 51 | 54.7 | | | |
| | | M-12 | 3 | 3.3 | | | |
| Synthesis | (A-10) | M-1 | 46 | 41.5 | 78.6 | 7200 | 1.45 |
| Example 10 | | M-2 | 51 | 55.1 | | | |
| | | M-13 | 3 | 3.4 | | | |
| Synthesis | (A-11) | M-1 | 46 | 41.2 | 79.1 | 7100 | 1.42 |
| Example 11 | | M-2 | 51 | 55.3 | | | |
| | | M-14 | 3 | 3.5 | | | |
| Synthesis | (A-12) | M-1 | 45 | 42.5 | 85.2 | 6600 | 1.53 |
| Example 12 | | M-2 | 35 | 37.3 | | | |
| | | M-12 | 6 | 6.3 | | | |
| | | M-9 | 14 | 13.9 | | | |
| Synthesis | (A-13) | M-2 | 51 | 55.4 | 80.2 | 6700 | 1.42 |
| Example 13 | | M-15 | 46 | 41.3 | | | |
| | | M-3 | 3 | 3.3 | | | |
| Synthesis | (A-14) | M-2 | 51 | 55.6 | 79.5 | 6600 | 1.44 |
| Example 14 | | M-16 | 46 | 41.2 | | | |
| | | M-4 | 3 | 3.2 | | | |
| Synthesis | (A-15) | M-2 | 51 | 55.1 | 81.2 | 6800 | 1.43 |
| Example 15 | | M-17 | 46 | 41.6 | | | |
| | | M-5 | 3 | 3.3 | | | |
| Synthesis | (B-1) | M-1 | 50 | 48.5 | 79.8 | 6900 | 1.42 |
| Example 16 | | M-2 | 50 | 51.5 | | | |
| Synthesis | (B-2) | M-1 | 35 | 33.8 | 86.2 | 6700 | 1.58 |
| Example 17 | | M-2 | 50 | 51.5 | | | |
| | | M-9 | 15 | 15 | | | |

### Synthesis of Polymer [D]

### Synthesis Example 18

35.8 g (70 mol %) of the compound (M-1) and 14.2 g (30 mol %) of the compound (M-8) were dissolved in 50 g of 2-butanone, and 3.2 g of dimethyl 2,2′-azobisisobutyrate was added to the solution to prepare a monomer solution. A three-necked flask (500 ml) was charged with 50 g of 2-butanone, purged with nitrogen for 30 minutes, and heated to 80° C. with stirring. The monomer solution was added dropwise to the flask over 3 hours using a dropping funnel. The monomers were polymerized for 6 hours from the start of dropwise addition of the monomer solution. After completion of polymerization, the polymer solution was cooled with water to 30° C. or less, and washed with 825 g of a methanol/2-butanone/hexane (=2/1/8) mixed solution. The solvent was replaced with propylene glycol monomethyl ether acetate to obtain a solution of a copolymer (D-1) (38.0 g (based on solid content), yield: 76%). The copolymer (D-1) had an Mw of 7000 and a dispersity (Mw/Mn) of 1.40. The ratio of the content of structural units derived from the compound (M-1) to the content of structural units derived from the compound (M-8) in the copolymer (D-1) (determined by ¹³C-NMR analysis) was 70.2:29.8 (mol %).

### Synthesis Example 19

16.5 g (40 mol %) of the compound (M-1), 26.8 g (50 mol %) of the compound (M-18), and 6.7 g (10 mol %) of the compound (M-19) were dissolved in 50 g of 2-butanone, and 3.2 g of dimethyl 2,2′-azobisisobutyrate was added to the solution to prepare a monomer solution. A three-necked flask (500 ml) was charged with 50 g of 2-butanone, purged with nitrogen for 30 minutes, and heated to 80° C. with stirring. The monomer solution was added dropwise to the flask over 3 hours using a dropping funnel. The monomers were polymerized for 6 hours from the start of dropwise addition of the monomer solution. After completion of polymerization, the polymer solution was cooled with water to 30° C. or less, and washed with 825 g of a methanol/2-butanone/hexane (=2/1/8) mixed solution. The solvent was replaced with propylene glycol monomethyl ether acetate to obtain a solution of a copolymer (D-2) (36.5 g (based on solid content), yield: 73%). The copolymer (D-2) had an Mw of 5000 and a dispersity (Mw/Mn) of 1.40. The ratio of the content of structural units derived from the compound (M-1), the content of structural units derived from the compound (M-18), and the content of structural units derived from the compound (M-19) in the copolymer (D-2) (determined by ¹³C-NMR analysis) was 40.2:49.6:10.2 (=(M-1):(M-18):(M-19)) (mol %).

### Preparation of Photoresist Composition

The acid generator [C], the nitrogen-containing compound [E], and the solvent [F] used to prepare the photoresist composition are shown below.

### Acid Generator [C]

C-1: compound represented by the following formula

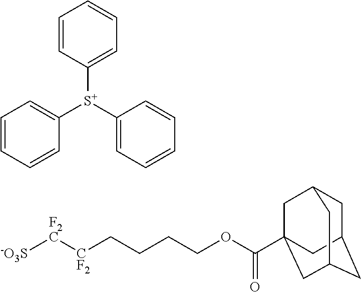

Nitrogen-containing compound [E]
E-1: compound represented by the following formula

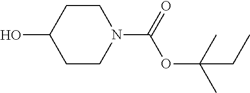

### Solvent [F]

F-1: propylene glycol monomethyl ether acetate
F-2: cyclohexanone
F-3: γ-butyrolactone

### Example 1

100 parts by mass of the polymer (A-1), 3 parts by mass of the fluorine-containing polymer (D-1), 1.1 parts by mass of the nitrogen-containing compound (E-1), 2220 parts by mass of the solvent (F-1), 950 parts by mass of the solvent (F-2), and 30 parts by mass of the solvent (F-3) were mixed. The resulting solution was filtered through a filter having a pore size of 0.2 μm to obtain a photoresist composition.

### Examples 2 to 22 and Comparative Examples 1 and 2

A photoresist composition was prepared in the same manner as in Example 1, except that the type and the amount of each component (polymer [A] or polymer [B], acid generator [C], and polymer [D]) were changed as shown in Tables 2 and 3. Note that the symbol “-” in Tables 2 and 3 indicates that the corresponding component was not used.

TABLE 2

| | | | | | Acid generator | | | | | | | | | |
|---|---|---|---|---|---|---|---|---|---|---|---|---|---|---|
| | Polymer [A] | | Polymer [B] | | [C] | | Polymer [D] | | | | | | | |
| | | Amount | | Amount | | Amount | | Amount | PB | | PEB | | | |
| | | (parts by | | (parts by | | (parts by | | (parts by | Temp. | Time | Temp. | Time | Sensitivity | Roughness |
| | Type | mass) | Type | mass) | Type | mass) | Type | mass) | (° C.) | (sec) | (° C.) | (sec) | (mJ/cm) | (nm) |
| Example 1 | A-1 | 100 | — | — | — | — | D-1 | 3 | 80 | 60 | 100 | 60 | 11 | 3.9 |
| Example 2 | A-2 | 100 | — | — | — | — | D-1 | 3 | 80 | 60 | 150 | 60 | 12 | 3.8 |
| Example 3 | A-3 | 100 | — | — | — | — | D-1 | 3 | 80 | 60 | 150 | 60 | 13 | 3.8 |
| Example 4 | A-4 | 100 | — | — | — | — | D-1 | 3 | 80 | 60 | 150 | 60 | 12 | 3.7 |
| Example 5 | A-5 | 100 | — | — | — | — | D-2 | 3 | 80 | 60 | 150 | 60 | 12 | 4.0 |
| Example 6 | A-2 | 100 | — | — | C-1 | 3 | D-1 | 3 | 80 | 60 | 100 | 60 | 9 | 4.2 |
| Example 7 | A-3 | 100 | — | — | C-1 | 3 | D-1 | 3 | 80 | 60 | 100 | 60 | 9 | 4.1 |
| Example 8 | A-4 | 100 | — | — | C-1 | 3 | D-1 | 3 | 80 | 60 | 100 | 60 | 10 | 4.0 |
| Example 9 | A-5 | 100 | — | — | C-1 | 3 | D-1 | 3 | 80 | 60 | 100 | 60 | 10 | 4.1 |
| Example 10 | A-9 | 100 | — | — | — | — | D-2 | 3 | 80 | 60 | 100 | 60 | 11 | 4.0 |
| Example 11 | A-10 | 100 | — | — | — | — | D-2 | 3 | 80 | 60 | 100 | 60 | 14 | 3.9 |
| Example 12 | A-13 | 100 | — | — | — | — | D-2 | 3 | 80 | 60 | 100 | 60 | 12 | 3.9 |
| Example 13 | A-14 | 100 | — | — | — | — | D-1 | 3 | 80 | 60 | 100 | 60 | 11 | 3.8 |
| Example 14 | A-15 | 100 | — | — | — | — | D-1 | 3 | 80 | 60 | 100 | 60 | 12 | 4.1 |
| Example 15 | A-11 | 100 | — | — | — | — | D-1 | 3 | 80 | 60 | 100 | 60 | 12 | 4.0 |
| Comparative | — | 100 | B-1 | 100 | C-1 | 10 | D-1 | 3 | 80 | 60 | 100 | 60 | 22 | 5.6 |
| Example 1 | | | | | | | | | | | | | | |

TABLE 3

| | Polymer [A] | | Polymer [B] | | Acid generator [C] | | PB | | PEB | | |
|---|---|---|---|---|---|---|---|---|---|---|---|
| | | Amount | | Amount | | Amount | Temp. | Time | Temp. | Time | Sensitivity |
| | Type | (parts by mass) | Type | (parts by mass) | Type | (parts by mass) | (° C.) | (sec) | (° C.) | (sec) | (μC/cm²) |
| Example 16 | A-6 | 100 | — | — | — | — | 80 | 60 | 150 | 60 | 21.0 |
| Example 17 | A-7 | 100 | — | — | — | — | 80 | 60 | 150 | 60 | 22.0 |
| Example 18 | A-8 | 100 | — | — | — | — | 80 | 60 | 150 | 60 | 21.0 |
| Example 19 | A-6 | 100 | — | — | C-1 | 3 | 80 | 60 | 100 | 60 | 15.0 |
| Example 20 | A-7 | 100 | — | — | C-1 | 3 | 80 | 60 | 100 | 60 | 16.0 |
| Example 21 | A-8 | 100 | — | — | C-1 | 3 | 80 | 60 | 100 | 60 | 16.0 |
| Example 22 | A-12 | 100 | — | — | — | — | 80 | 60 | 100 | 60 | 17.0 |
| Comparative | — | — | B-2 | 100 | C-1 | 10 | 80 | 60 | 100 | 60 | 42.0 |
| Example 2 | | | | | | | | | | | |

### Formation of Pattern (ArF Liquid Immersion Lithography)

A silicon wafer on which an underlayer antireflective film (“ARC66” manufactured by BREWER SCIENCE) (thickness: 105 nm) was formed, was used as a substrate. The photoresist composition (prepared in Examples 1 to 15 and Comparative Example 1) was spin-coated onto the substrate using a coater/developer (“CLEAN TRACK ACT 12” manufactured by Tokyo Electron, Ltd.). The applied photoresist composition was prebaked (PB) at 80° C. for 60 seconds on a hot plate to obtain a resist film having a thickness of 0.100 μm. The resist film was subjected to reduced projection exposure via a mask pattern (see below) and immersion water using an ArF immersion scanner (“S610C” manufactured by Nikon Corporation, NA: 1.30). The resist film was then subjected to post-exposure bake (PEB) for 60 seconds at the temperature shown in Table 2, developed at 23° C. for 30 seconds using butyl acetate, rinsed with 4-methyl-2-pentanol for 10 seconds, and dried to form a negative resist pattern. A pattern was also formed in the same manner as described above using methyl n-pentyl ketone, isoamyl acetate, or anisole as the developer.

### Evaluation of Sensitivity

An optimum dose at which a 0.055 μm hole was formed on the wafer by reduced projection exposure was determined to be an optimum dose, and taken as the sensitivity (mJ/cm²).

### Evaluation of Roughness

A silicon wafer on which an underlayer antireflective film (“ARC66” manufactured by BREWER SCIENCE) (thickness: 105 nm) was formed, was used as a substrate. The photoresist composition (prepared in Examples 1 to 15 and Comparative Example 1) was spin-coated onto the substrate using a coater/developer (“CLEAN TRACK ACT 12” manufactured by Tokyo Electron, Ltd.), and prebaked (PB) at 80° C. for 60 seconds on a hot plate to obtain a resist film having a thickness of 0.10 μm. The entire resist film was exposed at the optimum dose (sensitivity) shown in Table 2 using an ArF immersion scanner (“S610C” manufactured by Nikon Corporation, NA: 1.30), subjected to PEB for 60 seconds at the temperature shown in Table 2, developed at 23° C. for 30 seconds using butyl acetate, rinsed with 4-methyl-2-pentanol for 10 seconds, and dried. The surface roughness of the resist film was measured using an atomic force microscope (“NanoScope IIIa” manufactured by Digital Instrument) (measurement area: 40×40 μm). The results are shown in Table 2. A case where the roughness value (RMS) was less than 5.0 nm was evaluated as “Acceptable”, and a case where the roughness value (RMS) was 5.0 nm or more was evaluated as “Unacceptable”.

As shown in Table 2, the photoresist compositions of Examples 1 to 15 exhibited excellent sensitivity as compared with the photoresist composition of Comparative Example 1, and could suppress occurrence of roughness on the surface of the exposed area after development. Note that the above effects were also achieved when the pattern was formed using methyl n-pentyl ketone, isoamyl acetate, or anisole as the developer.

### Formation of Pattern (EB Exposure)

The photoresist composition (prepared in Examples 16 to 22 and Comparative Example 2) was spin-coated onto a silicon wafer using a coater/developer (“CLEAN TRACK ACT-8” manufactured by Tokyo Electron, Ltd.), and pre-baked (PB) under the conditions shown in Table 3 to form a resist film having a thickness of 40 nm. The resist film was exposed to electron beams using an electron beam drawing system (“HL800D” manufactured by Hitachi, Ltd., output: 50 KeV, current density: 5.0 A/cm²). The resist film was then subjected to PEB under the conditions shown in Table 3. The resist film was developed at 23° C. for 30 seconds using butyl acetate, rinsed with 4-methyl-2-pentanol for 10 seconds, and dried to form a negative resist pattern. A pattern was also formed in the same manner as described above using methyl n-pentyl ketone, isoamyl acetate, or anisole as the developer.

### Evaluation of Sensitivity

A dose at which a line-and-space pattern (1L1S) including a line (width: 130 nm) and a space (width: 130 nm) defined by the adjacent lines was formed at a 1:1 line width was determined to be an optimum dose, and the sensitivity (μC/cm²) was evaluated based on the optimum dose. The results are shown in Table 3.

As shown in Table 3, the photoresist compositions of Examples 16 to 22 exhibited significantly high sensitivity to electron beams as compared with the photoresist composition of Comparative Example 2, and could form a fine pattern with high accuracy.

Since the photoresist composition that is used for the negative pattern-forming method according to the embodiments of the invention includes the polymer that includes the structural unit (I) having an acid-generating capability, the photoresist composition exhibits excellent sensitivity, ensures that the exposed area is scarcely soluble in a developer that includes an organic solvent, and can suppress occurrence of roughness. Therefore, the negative pattern-forming method according to the embodiments of the invention can suppress occurrence of roughness, and form a fine pattern with high accuracy. Accordingly, the negative pattern-forming method according to the embodiments of the invention may be very useful for the production of semiconductor devices for which a further reduction in line width and the like will be desired in the future.

Obviously, numerous modifications and variations of the present invention are possible in light of the above teachings. It is therefore to be understood that within the scope of the appended claims, the invention may be practiced otherwise than as specifically described herein.

1. A negative pattern-forming method comprising:
providing a resist film on a substrate using a photoresist composition, the photoresist composition comprising:
a first polymer that includes a first structural unit having an acid-generating capability; and
an organic solvent;
exposing the resist film; and
developing the exposed resist film using a developer that includes an organic solvent.

2. The negative pattern-forming method according to claim 1, wherein the first structural unit has a structure derived from an onium salt, diazomethane, or N-sulfonyloxyimide.

3. The negative pattern-forming method according to claim 2, wherein the first structural unit is represented by a formula (1) or a formula (2), 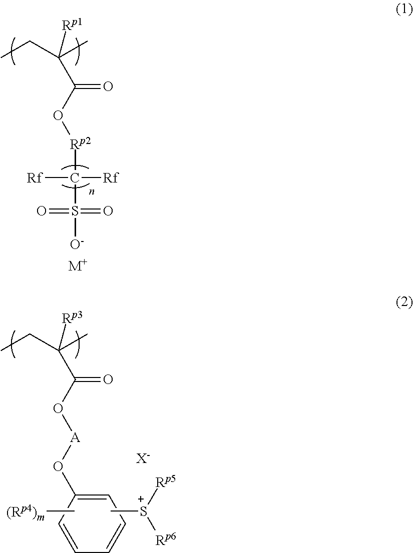
wherein
R^{p1} is a hydrogen atom, a fluorine atom, a trifluoromethyl group, or an alkyl group having 1 to 3 carbon atoms,
R^{p2} is a divalent organic group,
Rf are independently a hydrogen atom, a fluorine atom, or a fluoroalkyl group having 1 to 3 carbon atoms, n is an integer from 0 to 6,
M⁺ is an onium cation,
R^{p3} is a hydrogen atom, a fluorine atom, a trifluoromethyl group, or an alkyl group having 1 to 3 carbon atoms,
each of R^{p4}, R^{p5}, and R^{p6} is independently an organic group having 1 to 10 carbon atoms,
m is an integer from 0 to 3, wherein a plurality of R^{p4} are either identical or different in a case where m is 2 or 3,
A is a methylene group, an alkylene group having 2 to 10 carbon atoms, or an arylene group having 6 to 10 carbon atoms, and
X⁻ is a sulfonate anion, a carboxylate anion, or an amide anion.

4. The negative pattern-forming method according to claim 3, wherein M⁺ in the formula (1) is represented by a formula (3), 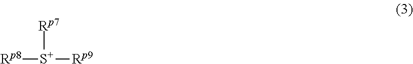
wherein each of R^{p7} to R^{p9} is independently a hydrocarbon group having 1 to 30 carbon atoms, and optionally R^{p7} and R^{p8} bond to each other to form a cyclic structure together with the sulfur atom to which R^{p7} and R^{p8} are bonded, wherein some or all of the hydrogen atoms of the hydrocarbon group represented by R^{p7} to R^{p9} are substituted with a substituent, or unsubstituted.

5. The negative pattern-forming method according to claim 3, wherein X⁻ in the formula (2) is represented by a formula (4),
R^{p10}—SO₃⁻ (4)
wherein R^{p10} is a monovalent organic group that includes a fluorine atom.

6. The negative pattern-forming method according to claim 1, wherein the first polymer further includes a second structural unit represented by a formula (5), 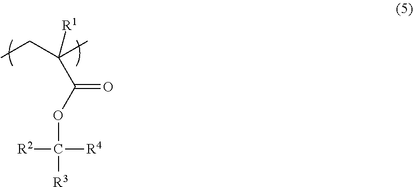
wherein
R¹ is a hydrogen atom, a fluorine atom, a trifluoromethyl group, or an alkyl group having 1 to 3 carbon atoms, and
each of R² to R⁴ is independently an alkyl group having 1 to 4 carbon atoms or an alicyclic hydrocarbon group having 4 to 20 carbon atoms, or
R² is an alkyl group having 1 to 4 carbon atoms or an alicyclic hydrocarbon group having 4 to 20 carbon atoms, and R³ and R⁴ taken together represent a divalent alicyclic hydrocarbon group having 4 to 20 carbon atoms together with the carbon atom to which R³ and R⁴ are bonded.

7. The negative pattern-forming method according to claim 1, wherein the photoresist composition further comprises a second polymer that does not include the first structural unit, but includes a second structural unit represented by a formula (5), 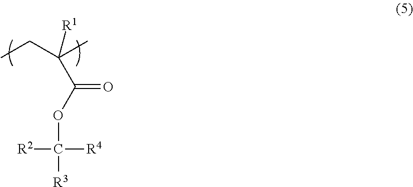
wherein
R¹ is a hydrogen atom, a fluorine atom, a trifluoromethyl group, or an alkyl group having 1 to 3 carbon atoms, and
each of R² to R⁴ is independently an alkyl group having 1 to 4 carbon atoms or an alicyclic hydrocarbon group having 4 to 20 carbon atoms, or
R² is an alkyl group having 1 to 4 carbon atoms or an alicyclic hydrocarbon group having 4 to 20 carbon atoms, and R³ and R⁴ taken together represent a divalent alicyclic hydrocarbon group having 4 to 20 carbon atoms together with the carbon atom to which R³ and R⁴ are bonded.

8. The negative pattern-forming method according to claim 1, wherein the photoresist composition further comprises an acid generator.

9. A photoresist composition comprising:
a first polymer that includes a first structural unit having an acid-generating capability; and
an organic solvent,
the photoresist composition being developed using an organic solvent, and being used to form a negative pattern.

10. The photoresist composition according to claim 9, wherein the first structural unit has a structure derived from an onium salt, diazomethane, or N-sulfonyloxyimide.

11. The photoresist composition according to claim 10, wherein the first structural unit is represented by a formula (1) or a formula (2), 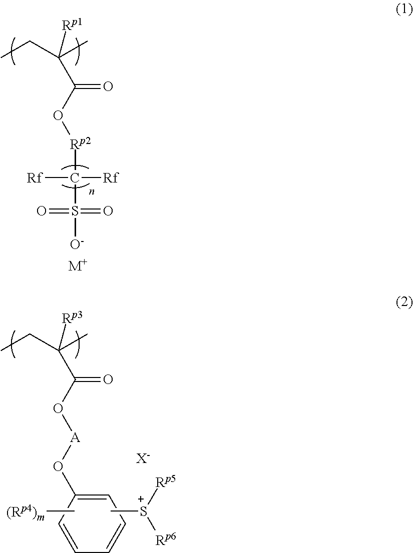
wherein
R^{p1} is a hydrogen atom, a fluorine atom, a trifluoromethyl group, or an alkyl group having 1 to 3 carbon atoms,
R^{p2} is a divalent organic group,
Rf are independently a hydrogen atom, a fluorine atom, or a fluoroalkyl group having 1 to 3 carbon atoms,
n is an integer from 0 to 6,
M⁺ is an onium cation,
R^{p3} is a hydrogen atom, a fluorine atom, a trifluoromethyl group, or an alkyl group having 1 to 3 carbon atoms,
each of R^{p4}, R^{p5}, and R^{p6} is independently an organic group having 1 to 10 carbon atoms,
m is an integer from 0 to 3, wherein a plurality of R^{p4} are either identical or different in a case where m is 2 or 3,
A is a methylene group, an alkylene group having 2 to 10 carbon atoms, or an arylene group having 6 to 10 carbon atoms, and
X⁻ is a sulfonate anion, a carboxylate anion, or an amide anion.
